(19) United States
(12) Patent Application Publication
(10) Pub. No.: US 2013/0169944 A1
(43) Pub. Date: Jul. 4, 2013

(54) EXPOSURE APPARATUS, EXPOSURE METHOD, DEVICE MANUFACTURING METHOD, PROGRAM, AND RECORDING MEDIUM

(71) Applicant: NIKON CORPORATION, Tokyo (JP)

(72) Inventors: Yasufumi NISHII, Kumagaya-shi (JP); Minoru ONDA, Ageo-shi (JP); Shinji SATO, Fukaya-shi (JP); Hiroyuki NAGASAKA, Kumagaya-shi (JP)

(73) Assignee: NIKON CORPORATION, Tokyo (JP)

(21) Appl. No.: 13/727,325

(22) Filed: Dec. 26, 2012

Related U.S. Application Data
(60) Provisional application No. 61/580,891, filed on Dec. 28, 2011.

(51) Int. Cl. G03F 7/20

(52) U.S. Cl. CPC G03F 7/70341
USPC 355/30

(57) ABSTRACT

An exposure apparatus that exposes a substrate with exposure light through a first liquid. The exposure apparatus includes: an optical member that has an emission surface which emits the exposure light; a first member that forms a first liquid immersion space of the first liquid in at least a part of a first space under the first lower surface and an optical path space including an optical path of the exposure light from the emission surface; and a second member that forms a second liquid immersion space of a second liquid, the second member being capable of moving in a state where the second liquid immersion space is formed separated from the first liquid immersion space.

### CROSS-REFERENCE TO RELATED APPLICATION

This application is a non-provisional application claiming priority to and the benefit of U.S. provisional application No. 61/580,891, filed on Dec. 28, 2011. The entire contents of which are incorporated herein by reference.

### BACKGROUND

1. Field of the Invention

The present invention relates to an exposure apparatus, an exposure method, a device manufacturing method, a program, and a recording medium.

2. Description of Related Art

In exposure apparatuses used in the photolithography process, for example, as disclosed in US Patent Application, Publication No. 2009/0046261, a liquid immersion exposure apparatus, which exposes a substrate with exposure light through a liquid, has been known.

### SUMMARY

In the liquid immersion exposure apparatus, for example, when a liquid flows out from a predetermined space, exposure defects are likely to occur. As a result, defective devices are likely to be produced.

According to an aspect of the present invention, an object is to provide an exposure apparatus and an exposure method capable of inhibiting exposure defects from occurring. Further, according to another aspect of the present invention, an object is to provide a device manufacturing method, a program, and a recording medium capable of inhibiting defective devices from being produced.

According to a first aspect of the present invention, there is provided an exposure apparatus that exposes a substrate with exposure light through a first liquid. The exposure apparatus includes: an optical member that has an emission surface which emits the exposure light; a first member that is disposed at at least a part of a surrounding of the optical member and forms a first liquid immersion space of the first liquid, the first member having a first lower surface to which an object can be opposed, the object being capable of moving to a position opposed to the emission surface, the first liquid immersion space being formed in at least a part of a first space under the first lower surface and an optical path space including an optical path of the exposure light from the emission surface; and a second member that is disposed outside the first member with respect to the optical path and forms a second liquid immersion space of a second liquid, the second member having a second lower surface to which the object can be opposed, the second liquid immersion space being formed in at least a second space under the second lower surface, the second member being capable of moving in a state where the second liquid immersion space is formed separated from the first liquid immersion space.

According to a second aspect of the present invention, there is provided a device manufacturing method including: exposing a substrate by using the exposure apparatus of the first aspect; and developing the exposed substrate.

According to a third aspect of the present invention, there is provided an exposure method of exposing a substrate with exposure light through a first liquid. The exposure method includes: forming a first liquid immersion space of the first liquid with a first member, the first member being disposed at at least a part of a surrounding of an optical member such that the first liquid fills an optical path of the exposure light between the substrate and an emission surface of the optical member that emits the exposure light and having a first lower surface to which the substrate opposed to the emission surface can be opposed, the first liquid immersion space being formed in at least a part of a first space under the first lower surface and an optical path space under the emission surface; exposing the substrate through the first liquid in the first liquid immersion space; forming a second liquid immersion space of a second liquid with a second member, the second member being disposed outside the first member with respect to the optical path and having a second lower surface to which the substrate can be opposed, the second liquid immersion space being formed in at least a part of a second space under the second lower surface; and moving the second member in the state where the second liquid immersion space is formed separated from the first liquid immersion space.

According to a fourth aspect of the present invention, there is provided a device manufacturing method including: exposing a substrate by using the exposure method of the third aspect; and developing the exposed substrate.

According to a fifth aspect of the present invention, there is provided a program causing a computer to control an exposure apparatus, which exposes a substrate with exposure light through a first liquid, by executing: forming a first liquid immersion space of the first liquid with a first member, the first member being disposed at at least apart of a surrounding of an optical member such that the first liquid fills an optical path of the exposure light between the substrate and an emission surface of the optical member that emits the exposure light and having a first lower surface to which the substrate opposed to the emission surface can be opposed, the first liquid immersion space being formed in at least a part of a first space under the first lower surface and an optical path space under the emission surface; exposing the substrate through the first liquid in the first liquid immersion space; forming a second liquid immersion space of a second liquid with a second member, the second member being disposed outside the first member with respect to the optical path and having a second lower surface to which the substrate can be opposed, the second liquid immersion space being formed in at least a part of a second space under the second lower surface; and moving the second member in the state where the second liquid immersion space is formed separated from the first liquid immersion space.

According to a sixth aspect of the present invention, there is provided a computer-readable recording medium storing the program of the fifth aspect.

According to the aspects of the present invention, it is possible to inhibit exposure defects from occurring. In addition, according to the aspects of the present invention, it is possible to inhibit defective devices from being produced.

### BRIEF DESCRIPTION OF THE DRAWINGS

FIG. 1 is a diagram illustrating an example of an exposure apparatus according to a first embodiment.

FIG. 2 is a diagram illustrating an example of substrate stage and measurement stage according to the first embodiment.

FIG. 3 is a cross-sectional view illustrating an example of a liquid immersion member according to the first embodiment.

FIG. 4 is a diagram of the liquid immersion member according to the first embodiment as viewed from the lower side.

FIG. 5 is a cross-sectional view illustrating a part of the liquid immersion member according to the first embodiment.

FIG. 6 is a cross-sectional view illustrating an example of the liquid immersion member according to the first embodiment.

FIG. 7 is a schematic diagram illustrating the liquid immersion member according to the first embodiment.

FIG. 8 is a diagram illustrating an example of a substrate stage according to the first embodiment.

FIG. 9 is a diagram illustrating an example of an operation of the exposure apparatus according to the first embodiment.

FIG. 10 is a diagram illustrating an example of the operation of the exposure apparatus according to the first embodiment.

FIG. 11 is a diagram illustrating an example of the operation of the exposure apparatus according to the first embodiment.

FIG. 12 is a diagram illustrating an example of the operation of the exposure apparatus according to the first embodiment.

FIG. 13 is a diagram illustrating an example of the operation of the exposure apparatus according to the first embodiment.

FIG. 14 is a diagram illustrating an example of the operation of the exposure apparatus according to the first embodiment.

FIG. 15 is a diagram illustrating an example of the liquid immersion member.

FIG. 16 is a diagram illustrating an example of the liquid immersion member.

FIG. 17 is a diagram illustrating an example of an exposure apparatus according to a second embodiment.

FIG. 18 is a diagram illustrating an example of the exposure apparatus according to the second embodiment.

FIG. 19 is a diagram illustrating an example of the exposure apparatus according to the second embodiment.

FIG. 20 is a diagram illustrating an example of the exposure apparatus according to the second embodiment.

FIG. 21 is a diagram illustrating an example of the exposure apparatus according to the second embodiment.

FIG. 22 is a diagram illustrating an example of an operation of an exposure apparatus according to a third embodiment.

FIG. 23 is a diagram illustrating an example of the substrate stage.

FIG. 24 is a diagram illustrating an example of an operation of the exposure apparatus according to the third embodiment.

FIG. 25 is a cross-sectional view illustrating an example of a liquid immersion member according to a fourth embodiment.

FIG. 26 is a diagram illustrating the liquid immersion member according to the fourth embodiment as viewed from the lower side.

FIG. 27 is a diagram illustrating an example of an operation of an exposure apparatus according to the fourth embodiment.

FIG. 28 is a diagram illustrating an example of the operation of the exposure apparatus according to the fourth embodiment.

FIG. 29 is a diagram illustrating an example of the operation of the exposure apparatus according to the fourth embodiment.

FIG. 30 is a diagram illustrating an example of the operation of the exposure apparatus according to the fourth embodiment.

FIG. 31 is a diagram illustrating an example of the operation of the exposure apparatus according to the fourth embodiment.

FIG. 32 is a diagram illustrating an example of an operation of an exposure apparatus according to a fifth embodiment.

FIG. 33 is a diagram illustrating an example of the operation of the exposure apparatus according to the fifth embodiment.

FIG. 34 is a diagram illustrating an example of the liquid immersion member.

FIG. 35 is a diagram illustrating an example of the liquid immersion member.

FIG. 36 is a diagram illustrating an example of the liquid immersion member.

FIG. 37 is a diagram illustrating an example of the substrate stage.

FIG. 38 is a flowchart illustrating an example of a device manufacturing method.

### DESCRIPTION OF EMBODIMENTS

Hereinafter, embodiments of the present invention will be described with reference to the drawings, but the present invention is not limited to these embodiments. In the following description, an XYZ orthogonal coordinate system is established, and the positional relationship of respective sections will be described with reference to the XYZ orthogonal coordinate system. It is assumed that a predetermined direction in a horizontal plane is an X axis direction, a direction orthogonal to the X axis direction in the horizontal plane is a Y axis direction, and a direction (that is, the vertical direction) orthogonal to the X axis direction and the Y axis direction is a Z axis direction. Further, it is assumed that rotation (tilt) directions around the X axis, the Y axis, and the Z axis are respectively θX, θY, and θZ directions.

### First Embodiment

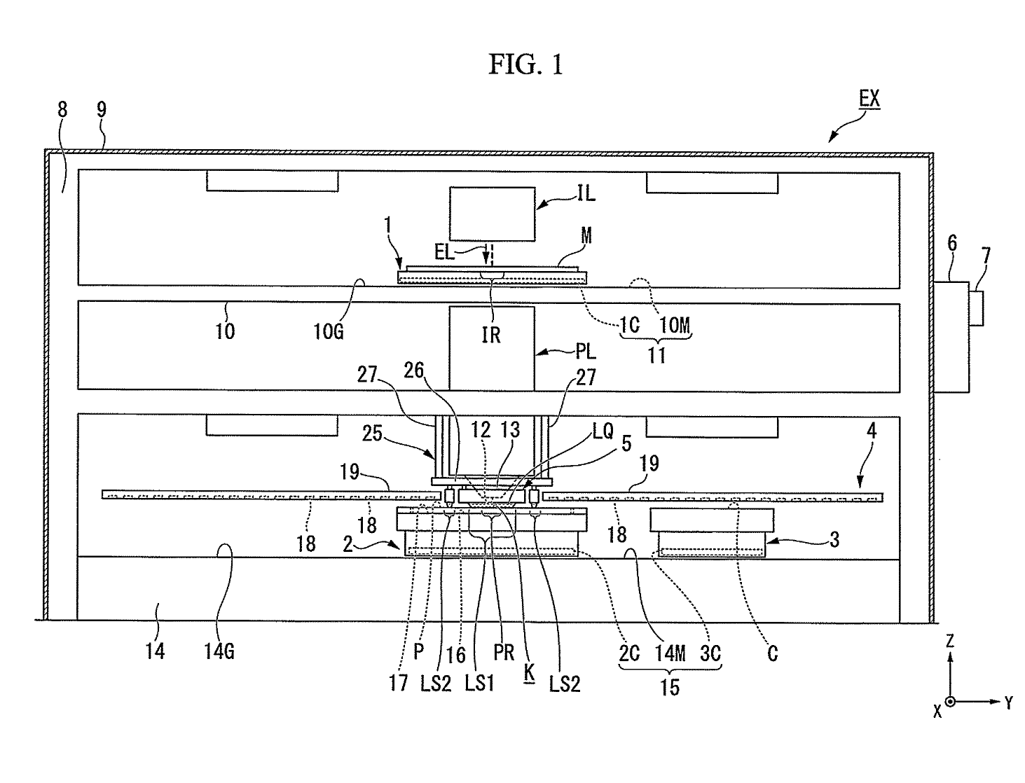

The first embodiment will be described. FIG. 1 is a schematic configuration diagram illustrating an example of an exposure apparatus EX according to the first embodiment. The exposure apparatus EX of the present embodiment is an immersion exposure apparatus which exposes a substrate P with exposure light EL through a liquid LQ. In the present embodiment, a liquid immersion space LS1 is formed such that the optical path K of the exposure light EL with which the substrate P is irradiated is filled with the liquid LQ. The liquid immersion space is a section (space, region) filled with the liquid. The substrate P is exposed with the exposure light EL through the liquid LQ within the liquid immersion space LS1 (first liquid immersion space). In the present embodiment, water (pure water) is used as the liquid LQ.

Further, the exposure apparatus EX of the present embodiment is an exposure apparatus which has a substrate stage and a measurement stage as disclosed in for example U.S. Pat. No. 6,897,963, EP Patent Application, Publication No. 1713113, and the like.

In FIG. 1, the exposure apparatus EX includes: a mask stage 1 that is movable while holding a mask M; a substrate stage 2 that is movable while holding the substrate P; a measurement stage 3 that is movable with a measurement member (measurement instrument) C, which measures the exposure light EL, mounted thereon without holding the substrate P; a measurement system 4 that measures positions of the mask stage 1, the substrate stage 2, and the measurement stage 3; an illumination system IL that illuminates the mask M with exposure light EL; a projection optical system PL that projects an image of a pattern of the mask M, illuminated with exposure light EL, onto the substrate P; a liquid immersion member 5 that forms the liquid immersion space LS1; a control device 6 that controls operations of the entire exposure apparatus EX; and a storage device 7 that is connected to the control device 6 and stores various kinds of information on the exposure.

Further, the exposure apparatus EX includes a body (frame) 8 that supports at least the projection optical system PL; and a chamber device 9 that adjusts the environment (at least one of a temperature, a humidity, a pressure, and a degree of cleanliness) of a space through which the exposure light EL travels.

The mask M includes reticles on which are formed device patterns for projection onto the substrate P. The mask M includes, for example, a transparent plate such as a glass plate, and a transmissive mask which has a pattern formed on the transparent plate by using a light shielding material such as chromium. It should be noted that, a reflective mask may be used as the mask M.

The substrate P is a substrate used to manufacture devices. The substrate P includes, for example, a base such as a semiconductor wafer and a photosensitive film formed on the base. A photosensitive film is a film of a photosensitive material (photoresist). Further, the substrate P may include a separate film in addition to the photosensitive film. For example, the substrate P may include an antireflective film, and may include a protective film (topcoat film) which protects the photosensitive film.

The illumination system IL irradiates the exposure light EL onto a predetermined illumination region IR. The illumination region IR includes a position to which the exposure light EL emitted from the illumination system IL can be irradiated. The illumination system IL illuminates at least a part of the mask M, which is disposed on the illumination region IR, with the exposure light EL having a uniform luminance distribution. As the exposure light EL emitted from the illumination system IL, for example, bright lines (g-line, h-line, i-line) emitted from a mercury lamp, deep ultraviolet (DUV) light such as KrF excimer laser light (wavelength 248 nm), and vacuum ultraviolet (VUV) light such as ArF excimer laser light (wavelength 193 nm), and F₂ laser light (wavelength 157 nm) may be used. In the present embodiment, ArF excimer laser light, which is ultraviolet light (vacuum ultraviolet light), is used as the exposure light EL.

The mask stage 1 is movable, while holding the mask M, on a guiding surface 10G of a base member 10 including the illumination region IR. In the present embodiment, the guiding surface 10G is substantially parallel to the XY plane.

The mask stage 1 is moved by an operation of a driving system 11 including a planar motor disclosed in, for example, U.S. Pat. No. 6,452,292. In the present embodiment, the driving system 11 has a slider 1C, which is disposed on the mask stage 1, and a stator 10M which is disposed on the base member 10. In the present embodiment, the mask stage 1 is movable in six directions along the guiding surface 10Q that is, the X axis, Y axis, Z axis, θX, θY, and θZ directions, by the operation of the driving system 11. It should be noted that the driving system 11 may not include the planar motor. For example, the driving system 11 may include a linear motor.

The projection optical system PL irradiates the exposure light EL onto a predetermined projection region PR. The projection region PR includes a position to which the exposure light EL emitted from the projection optical system PL can be irradiated. The projection optical system PL projects an image of the pattern of the mask M, with a predetermined projection magnification, to at least a part of the substrate P, which is disposed in the projection region PR. The projection optical system PL of the present embodiment is a reduction system that has a projection magnification of, for example, ¼, ⅕, or ⅛. Furthermore, the projection optical system PL may be a unity magnification system or an enlargement system. In the present embodiment, an optical axis AX of the projection optical system PL is parallel to the Z axis. In addition, the projection optical system PL may be a dioptric system that does not include catoptric elements, a catoptric system that does not include dioptric elements, or a catadioptric system that includes both catoptric and dioptric elements. In addition, the projection optical system PL may form either an inverted or an erect image.

The projection optical system PL includes a terminal optical element 13 having an emission surface 12 from which the exposure light EL is emitted. From the emission surface 12, the exposure light EL is emitted toward the imaging plane of the projection optical system PL. The terminal optical element 13 is an optical element, which is closest to the imaging plane of the projection optical system PL, among the plurality of optical elements of the projection optical system PL. The projection region PR includes a position to which the exposure light EL emitted from the emission surface 12 can be irradiated. In the present embodiment, the emission surface 12 faces the −Z direction and is parallel to the XY plane. Further, the emission surface 12, which faces the −Z direction, may be a convex or concave surface. It should be noted that the emission surface 12 may be tilted with respect to the XY plane and may include a curved surface. In the present embodiment, the optical axis of the terminal optical element 13 is parallel to the Z axis. In the present embodiment, the exposure light EL emitted from the emission surface 12 travels in the −Z direction.

The substrate stage 2 is movable in the XY plane, which includes a position (projection region PR) irradiated with the exposure light EL from the emission surface 12, while holding the substrate P. The measurement stage 3 is movable in the XY plane, which includes the position (projection region PR) irradiated with the exposure light EL, from the emission surface 12, with the measurement member (measurement instrument) C mounted thereon. Each of the substrate stage 2 and the measurement stage 3 is movable on a guiding surface 14G of a base member 14. In the present embodiment, the guiding surface 14G is substantially parallel to the XY plane.

The substrate stage 2 and the measurement stage 3 are moved by the operation of the driving system 15 including a planar motor disclosed in for example U.S. Pat. No. 6,452,292. The driving system 15 has a slider 2C which is disposed on the substrate stage 2, a slider 3C which is disposed on the measurement stage 3, and a stator 14M which is disposed on the base member 14. Both of the substrate stage 2 and measurement stage 3 are movable in six directions along the guiding surface 14G, that is, the X axis, Y axis, Z axis, θX, θY, and θZ directions, by the operation of the driving system 15. It should be noted that the driving system 15 may not include the planar motor. For example, the driving system 15 may include a linear motor.

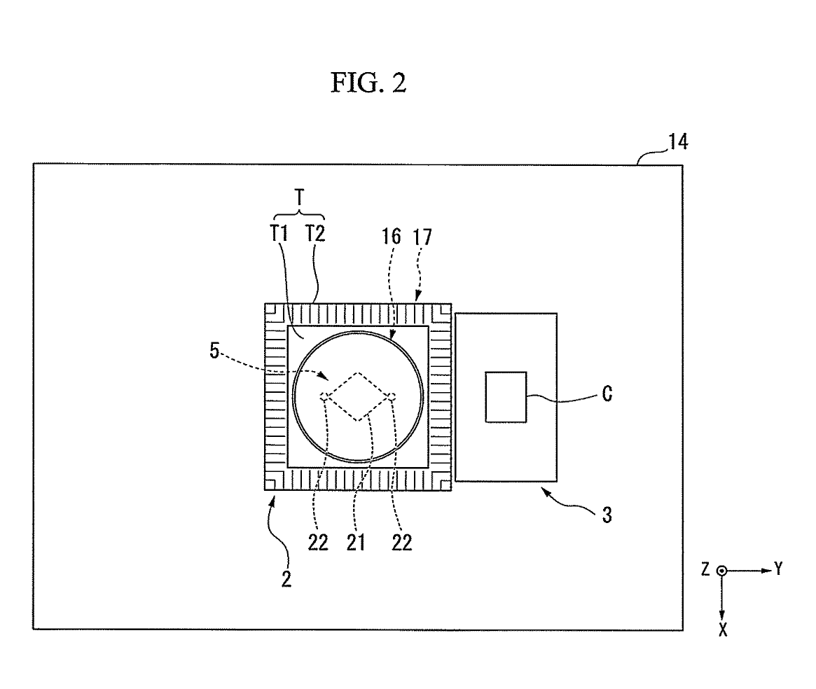

FIG. 2 is a top plan view illustrating an example of the substrate stage 2 and the measurement stage 3. As shown in FIGS. 1 and 2, the substrate stage 2 has a first holding section 16 which releasably holds the substrate P; and a second holding section 17 which releasably holds an enclosing member T such that it is disposed at at least a part of a surrounding of the substrate P held by the first holding section 16. The first holding section 16 and the second holding section 17 include, for example, a pin chuck mechanism. The enclosing member T includes a cover member T1 which is disposed around the substrate P held by the first holding section 16 and a scale member T2 which is disposed around a cover member T1. It should be noted that the cover member T1 may be disposed on only a part of the periphery of the substrate P. The scale member T2 may be disposed on only a part of the periphery of the cover member T1.

The measurement system 4 includes an interferometer system. The interferometer system includes: a unit that irradiates a measurement mirror of the mask stage 1 with measurement light so as to measure the position of the mask stage 1; and a unit that irradiates a measurement mirror of the substrate stage 2 and a measurement mirror of the measurement stage 3 with the measurement light so as to measure the positions of the substrate stage 2 and the measurement stage 3.

Further, the measurement system 4 includes an encoder system disclosed in for example US Patent Application, Publication No. 2007/0288121. The encoder system has an irradiation device that emits the measurement light and a light receiving device that receives the measurement light. In the system, the grid (scale, grid line), which belongs to the scale member T2, is irradiated with the measurement light emitted from the irradiation device, and the light receiving device receives the measurement light transmitted through the grid. The encoder system also has a plurality of encoder heads 18 that measures the position of the grid and a holding member 19 that holds the encoder heads 18.

It should be noted that the measurement system 4 may include only either one of the interferometer system and the encoder system. When the measurement system includes only the interferometer system, the scale member T2 of the substrate stage 2 can be omitted. In addition, the encoder system may employ a configuration wherein the encoder head is disposed at the substrate stage 2 and the scale member T2 is secured above the substrate stage 2.

When an exposure process or a predetermined measurement process is performed on the substrate P, the control device 6 controls the positions of the mask stage 1 (mask M), the substrate stage 2 (substrate P), and the measurement stage 3 (measurement member C) based on the measurement results of the measurement system 4.

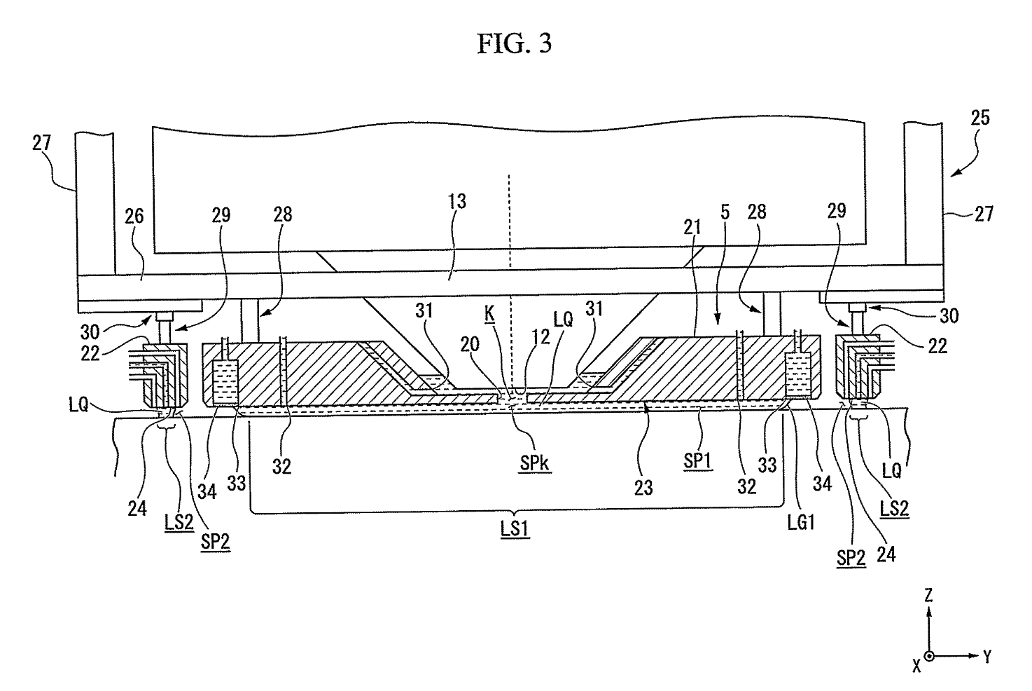

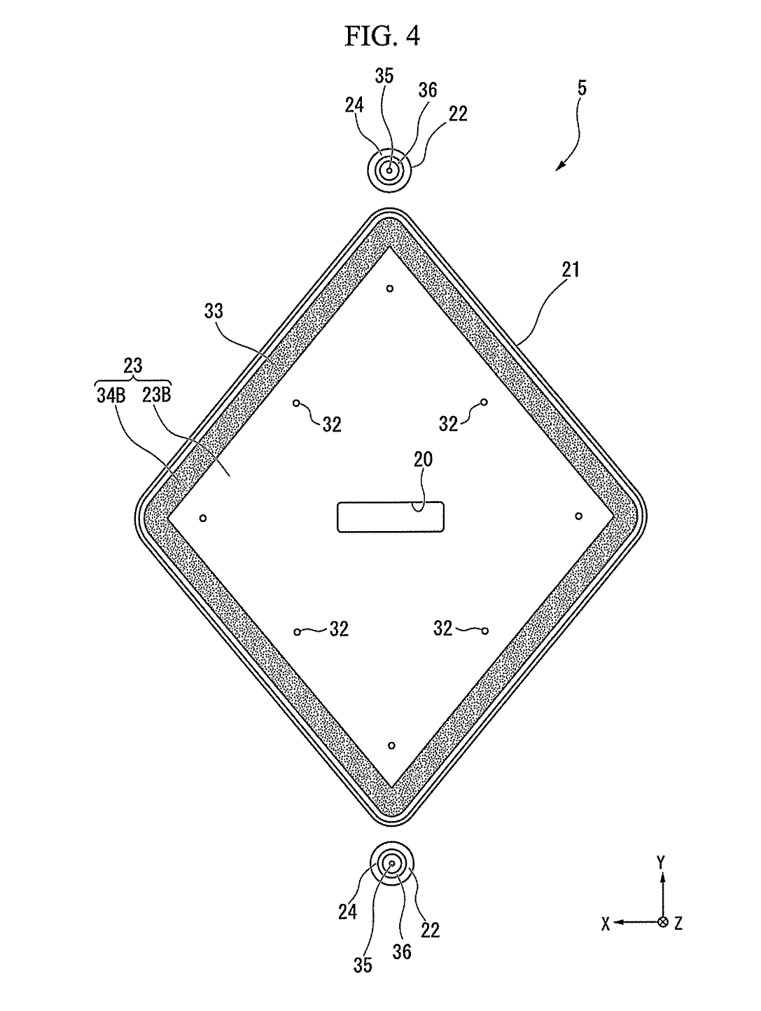

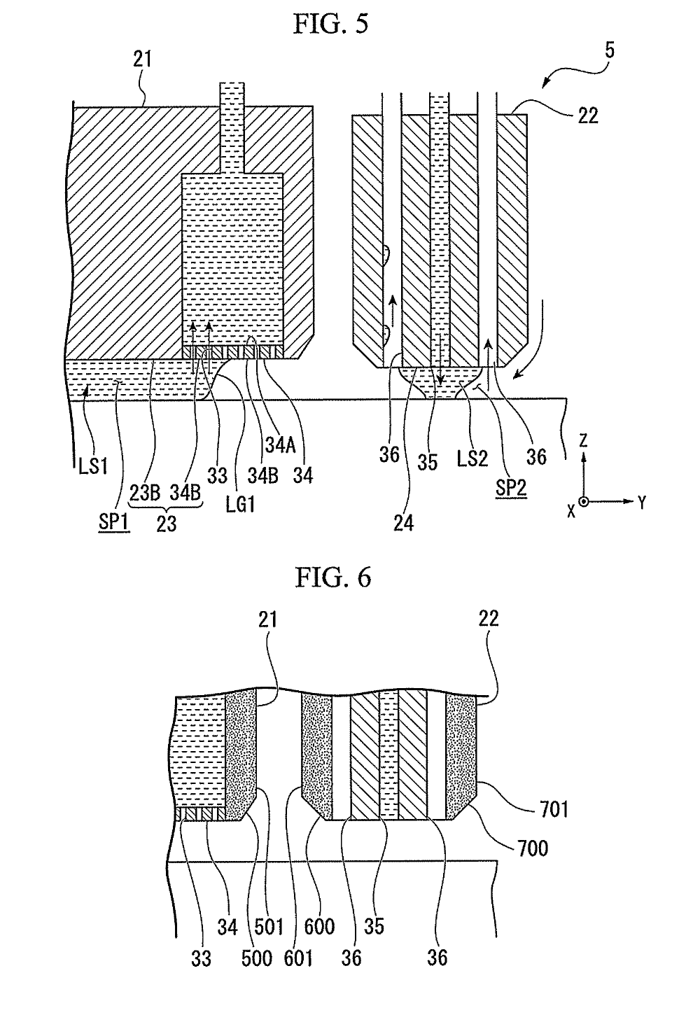

Next, the liquid immersion member 5 according to the present embodiment will be described. FIG. 3 is a side cross-sectional view illustrating an example of the liquid immersion member 5 according to the present embodiment in parallel to the YZ plane. FIG. 4 is a diagram illustrating the liquid immersion member 5 as viewed from the lower side (−Z side). FIG. 5 is a diagram illustrating a part of FIG. 3 in an enlarged manner.

In the present embodiment, the liquid immersion member 5 includes: a first member 21 that is disposed at at least a part of a surrounding of the terminal optical element 13 and has a lower surface 23; and second members 22 that are disposed outside the first member 21 with respect to the optical path K (the optical axis of the terminal optical element 13) of the exposure light EL emitted from the emission surface 12 and has a lower surface 24.

The lower surface 23 can be opposed to the object which is movable in the XY plane including the position opposed to the emission surface 12. The lower surface 24 can be opposed to the object which is movable in the XY plane including the position opposed to the emission surface 12.

The object which is movable in the XY plane including the position opposed to the emission surface 12 includes an object which can be opposed to the emission surface 12, and includes an object which can be disposed in the projection region PR. In the present embodiment, the object includes at least one of at least a part of the substrate stage 2 (for example, the enclosing member T of the substrate stage 2), the substrate P which is held by the substrate stage 2 (the first holding section 16), and the measurement stage 3. In the exposure of the substrate P, the liquid immersion space LS1 is formed such that the optical path K of the exposure light EL with which the substrate P is irradiated is filled with the liquid LQ. When the substrate F is irradiated with the exposure light EL, the liquid immersion space LS1 is formed such that only the area of a part of the surface of the substrate P including the projection region PR is covered with the liquid LQ.

In the following description, it is assumed that the object opposed to the emission surface 12 is the substrate P. It should be noted that, as described above, the object, which can be opposed to the emission surface 12, may be at least one of the substrate stage 2 and the measurement stage 3, and may be an object different from the substrate P, the substrate stage 2, and the measurement stage 3. Further, the liquid immersion space LS may be formed over the enclosing member T of the substrate stage 2 and the substrate P, and the liquid immersion space LS may be formed over the substrate stage 2 and the measurement stage 3.

The first member 21 forms the liquid immersion space LS1 of the liquid LQ in at least a part of the space SP1 close to the lower surface 23 (under the lower surface 23) and the space SPK including the optical path K close to the emission surface 12 (under the emission surface 12). Each second member 22 forms a liquid immersion space LS2 (second liquid immersion space) of the liquid LQ in at least a part of the space SP2 close to the lower surface 24 (under the lower surface 24). The liquid immersion space LS2 is separated from the liquid immersion space LS1.

In the present embodiment, the second member 22 is movable in a state where the liquid immersion space LS2 of the liquid LQ is formed to be separated from the liquid immersion space LS1. The second member 22 is movable to decrease the relative velocity between itself and the substrate P (object). The second member 22 is movable such that the relative velocity between itself and the substrate P (object) decreases less than a relative velocity between the first member 21 and the substrate P (object).

In the present embodiment, the space SPK includes a space between the emission surface 12 and the upper surface of the substrate P. The space SP1 includes a space between the lower surface 23 and the upper surface of the substrate P. The space SP2 includes a space between the lower surface 24 and the upper surface of the substrate P.

In the present embodiment, a part of the first member 21 is disposed at at least the part of the surrounding of the terminal optical element 13. Further, a part of the first member 21 is disposed at at least a part of a surrounding of the optical path K of the exposure light EL emitted from the emission surface 12.

In the present embodiment, the first member 21 is an annular member. In the present embodiment, a part of the first member 21 is disposed around the terminal optical element 13. Further, in the present embodiment, a part of the first member 21 is disposed at the surrounding of the optical path K of the exposure light EL between the terminal optical element 13 and the substrate P.

It should be noted that the first member 21 may not be the annular member. For example, the first member 21 may be disposed the part of the surrounding of the terminal optical element 13 and the optical path K. Further, the first member 21 may be disposed at at least the part of the surrounding of the terminal optical element 13. For example, the first member 21 may be disposed at at least the part of the surrounding of the optical path K between the emission surface 12 and the substrate P, and may not be disposed around the terminal optical element 13. Furthermore, the first member 21 may not be disposed at at least the part of the surrounding of the optical path K between the emission surface 12 and the substrate P. For example, the first member 21 may be disposed at at least the part of the surrounding of the terminal optical element 13, and may not be disposed at the surrounding of the optical path K between the emission surface 12 and the object.

The terminal optical element 13 is able to hold the liquid LQ between itself and the substrate P. The emission surface 12 opposed to the substrate P is able to hold the liquid LQ between itself and the substrate P. Further, the first member 21 is able to hold the liquid LQ between itself and the substrate P. The lower surface 23 opposed to the substrate P is able to hold the liquid LQ between itself and the substrate P. The liquid immersion space LS1 is formed by the liquid LQ which is held between the substrate P and each of the terminal optical element 13 and the first member 21. The liquid LQ is held between each of the emission surface 12 and the lower surface 23 on one side and the upper surface of the substrate P on the other side, thereby forming the liquid immersion space LS1 such that the optical path K of the exposure light EL between the terminal optical element 13 and the substrate P is filled with the liquid LQ.

The first member 21 forms the liquid immersion space LS1 of the liquid LQ in the space SPK close to the emission surface 12 (under the emission surface 12) such that the optical path K is filled with the liquid LQ. In the present embodiment, the first member 21 forms the liquid immersion space LS1 of the liquid LQ in at least apart of the space SP1 close to the lower surface 23 (under the lower surface 23).

For example, in the exposure of the substrate P, the first member 21 forms the liquid immersion space LS1 such that the optical path K of the exposure light EL, with which the substrate P is irradiated, is filled with the liquid LQ. When the substrate P is irradiated with the exposure light EL, the liquid immersion space LS1 is formed such that the area of a part of the surface of the substrate P including the projection region PR is covered with the liquid LQ.

In the present embodiment, at least a part of an interface (a meniscus or an edge) LG1 of the liquid LQ within the liquid immersion space LS1 is formed between the lower surface 23 and the upper surface of the substrate P. That is, the exposure apparatus EX of the present embodiment adopts a local liquid immersion method. The outside (the outside of the interface LG1) of the liquid immersion space LS1 is a gas space.

In the present embodiment, the first member 21 has a hole (opening) 20 opposed to the emission surface 12. The exposure light EL, which is emitted from the emission surface 12, is transmitted through the opening 20, and the substrate P can be irradiated with the light.

The second member 22 is disposed outside the first member 21 with respect to the optical path K (the optical axis of the terminal optical element 13). The first member 21 and the second member 22 are different members. The second member 22 is separated from the first member 21. The second member 22 is disposed a part of a surrounding of the first member 21.

The second member 22 is able to hold the liquid LQ between itself and the substrate P. The lower surface 24 opposed to the substrate P is able to hold the liquid LQ between itself and the substrate P. The liquid immersion space LS2 is formed by the liquid LQ which is held between the second member 22 and the substrate P. The liquid LQ is held between the lower surface 24 on one side and the upper surface of the substrate P on the other side, thereby forming the liquid immersion space LS2 a part of a surrounding of the liquid immersion space LS1.

In the present embodiment, two second members 22 are disposed in the space around the first member 21. In the present embodiment, the second member 22 is disposed on one side (+Y side) and the other side (−Y side) of the first member 21 with respect to the Y axis direction. It should be noted that the second member 22 may be disposed only on one side (+Y side) of the first member 21, and may be disposed only on the other side (−Y side).

In the present embodiment, the liquid immersion space LS2 is smaller than the liquid immersion space LS1. In addition, the size of the liquid immersion space includes the volume of the liquid forming the liquid immersion space. Further, the size of the liquid immersion space includes the weight of the liquid forming the liquid immersion space. Furthermore, the size of the liquid immersion space includes, for example, the area of the liquid immersion space in the plane (in the XY plane) parallel to the surface (upper surface) of the substrate P. Moreover, the size of the liquid immersion space includes, for example, the dimensions of the liquid immersion space in a predetermined direction (for example, the X axis direction, or the Y axis direction) in the plane (in the XY plane) parallel to the surface (upper surface) of the substrate P. In the present embodiment, in the plane (in the XY plane) parallel to the surface (upper surface) of the substrate P, the liquid immersion space LS2 is smaller than the liquid immersion space LS1.

In the present embodiment, at least a part of the lower surface 23 is substantially parallel to the XY plane. Further, in the present embodiment, at least a part of the lower surface 24 is substantially parallel to the XY plane. It should be noted that at least a part of the lower surface 23 may be tilted with respect to the XY plan; and may include a curved surface. At least a part of the lower surface 24 may be tilted with respect to the XY plane, and may include a curved surface.

In the present embodiment, the position (height) of the lower surface 23 in the Z axis direction is different from the position (height) of the lower surface 24. For example, as shown in FIG. 5, the lower surface 24 is disposed at a position lower than the lower surface 23. That is, the distance between the lower surface 23 and the surface of the object is greater than the distance between the lower surface 24 and the surface of the object. It should be noted that the lower surface 24 may be disposed at a position higher than the lower surface 23. That is, the distance between the lower surface 23 and the surface of the object may be smaller than the distance between the lower surface 24 and the surface of the object. It should be noted that the height of the lower surface 23 may be equal to the height of the lower surface 24. That is, the distance between the lower surface 23 and the surface of the object may be equal to the distance between the lower surface 24 and the surface of the object.

In the present embodiment, in the XY plane which is substantially parallel to the upper surface of the substrate P (object), the shape of the lower surface 23 is substantially rectangular. It should be noted that, as shown in FIG. 4 and the like, in the present embodiment, the corners (vertices) of the lower surface 23 of which the shape is rectangular are rounded. In the present embodiment, the corners of the lower surface 23 are respectively disposed on the +Y side, the −Y side, the +X side, and the −X side with respect to the optical path K.

In the present embodiment, in the XY plane, the shape of the lower surface 24 is substantially circular.

In the present embodiment, the first member 21 and the second member 22 are supported by the body (or frame) 8 with a supporting device 25 interposed therebetween. The position of the body 8 is substantially fixed. The supporting device 25 supports the first member 21 and the second member 22 above the object (such as the substrate P).

In the present embodiment, the supporting device 25 includes: a supporting member 26 that is connected to the first member 21 and the second member 22; and a connecting member 27 that connects the supporting member 26 and the body 8. In the present embodiment, the positions of the supporting member 26 and connecting member 27 are substantially fixed. In other words, the relative positions of the supporting member 26 and the connecting member 27 to the body 8 are not changed.

In the present embodiment, the supporting device 25 includes: a first supporting mechanism 28 that connects the first member 21 and the supporting member 26; and a second supporting mechanism 29 that connects the second member 22 and the supporting member 26.

In the present embodiment, the first supporting mechanism 28 supports the first member 21 without changing the position of the first member 21 relative to the supporting member 26. That is, in the present embodiment, the position of the first member 21 is not changed.

It should be noted that the first member 21 may be movable in at least one direction out of a direction (Z axis direction) parallel to the optical axis of the terminal optical element 13, a direction (θZ direction) around the axis parallel to the optical axis of the terminal optical element 13, a direction (at least one of the X axis direction and the Y axis direction) perpendicular to the optical axis of the terminal optical element 13, and a direction (at least one of the θX direction and the θY direction) around the axis perpendicular to the optical axis of the terminal optical element 13. For example, the first member 21 may be movable in six directions of the X axis, Y axis, Z axis, θX, θY, and θZ directions. Further, the first member 21 may be supported to be actively movable by the first supporting mechanism 2S. For example, the first supporting mechanism 28 may have a driving system including an actuator which is able to move the first member 21. Furthermore, the first member 21 may be supported to be passively movable by the first supporting mechanism 28. For example, the first supporting mechanism 28 may have an elastic mechanism which includes a spring member, a bellows member, and the like.

The second supporting mechanism 29 movably supports the second member 22. The second supporting mechanism 29 supports the second member 22 so as to change the position of the second member 22 relative to the supporting member 26. That is, in the present embodiment, the position of the second member 22 can be changed. In other words, the relative position between the second member 22 and the supporting member 26 can be changed. That is in the present embodiment, the second supporting mechanism 29 movably supports the second member 22 relative to the terminal optical element 13 and the first member 21.

The second member 22 is movable in at least one direction out of six directions of the X axis, Y axis, Z axis, θX, θY, and θZ directions.

The second member 22 may be movable in parallel to, for example, the XY plane. Further, the second member 22 may be movable in substantially parallel to the upper surface of the substrate P (object) opposed to the lower surface 24. For example, when the upper surface of the object such as the substrate P is parallel to the XY plane, the second member 22 may be movable in parallel to the XY plane. Furthermore, when the upper surface of the object is tilted with respect to the XY plane, the second member 22 may be movable in parallel to the upper surface of the object.

Further, in the present embodiment, the second member 22 may be movable in substantially parallel to the surface perpendicular to the optical axis of the terminal optical element 13. For example, when the optical axis of the terminal optical element 13 is parallel to the Z axis, the second member 22 may be movable in substantially parallel to the XY plane perpendicular to the optical axis.

Furthermore, in the present embodiment, the second member 22 may be movable to approach the upper surface of the object opposed to the lower surface 24 or to be separated from the upper surface of the object.

In addition, in the present embodiment, the second member 22 may be movable in substantially parallel to the optical axis of the terminal optical element 13. For example, when the optical axis of the terminal optical element 13 is parallel to the Z axis, the second member 22 is movable in substantially parallel to the Z axis.

Moreover, in the present embodiment, the second member 22 may be tilted with respect to the upper surface of the object opposed to the lower surface 24. Further, the second member 22 may be tilted with respect to the surface perpendicular to the optical axis of the terminal optical element 13.

In the present embodiment, the second member 22 is movable in the three directions of the X axis, Y axis, and Z axis directions.

In the present embodiment, the second member 22 is supported to be actively movable by the second supporting mechanism 29. In the present embodiment, the second supporting mechanism 29 has a driving system 30 including an actuator which is able to move the second member 22. The driving system 30 is able to move the second member 22 in three directions of the X axis, Y axis, and Z axis directions. It should be noted that the driving system 30 may include a counter mass that compensates the reaction (reactive force) caused by the movement of the second member 22, and may let the reaction (reactive force) out to the plate on which the exposure apparatus EX is provided.

In the present embodiment, the first member 21 has supply ports 31 and 32 that supply the liquid LQ for forming the liquid immersion space LS1; and a collection port 33 that collects at least a part of the liquid LQ within the liquid immersion space LS1.

The supply port 31 is disposed to face the optical path K. The supply port 31 is connected to a liquid supply device that is able to supply the liquid LQ through a supply channel formed inside the first member 21. The supply port 31 supplies the liquid LQ from the liquid supply device to the emission surface 12 side (space SPK).

The supply port 32 is disposed to be opposed to the object opposed to the lower surface 23. The supply port 32 is connected to the liquid supply device, which is able to supply the liquid LQ, through the supply channel formed inside the first member 21. The supply port 32 supplies the liquid LQ from the liquid supply device to the lower surface 23 side (space SP1). It should be noted that the supply port 32 does not have to be provided.

The collection port 33 is disposed to be opposed to the object opposed to the lower surface 23. The collection port 33 is connected to a liquid collecting device, which is able to collect (suction) the liquid LQ through the collecting channel formed inside the first member 21. The collection port 33 collects (suctions) at least a part of the liquid LQ within the space SP1.

In the present embodiment, the first member 21 has a porous member 34. The porous member 34 is disposed to face the space SP1. The porous member 34 has a plurality of holes (openings or pores) through which the liquid LQ is capable of flowing. The porous member 34 includes, for example, a mesh filter. The mesh filter is a porous member in which numerous small holes are formed as a mesh.

In the present embodiment, the porous member 34 is a plate-like member. The porous member 34 has a lower surface 34B that faces the space SP1; an upper surface 34A that faces the collecting channel formed in the first member 21; and a plurality of holes which are formed to connect the upper surface 34A and the lower surface 34B. In the present embodiment, the collection port 33 includes the holes of the porous member 34. The liquid LQ, which is collected through the holes (collection port 33) of the porous member 34, flows in the collecting channel.

In the present embodiment, only the liquid LQ is substantially collected through the porous member 34, and the collection of gas is limited. The control device 6 adjusts the difference between the pressure (the pressure of the space SP1) of the lower surface 34B side of the porous member 34 and the pressure (the pressure of the collecting channel) of the upper surface 34A side so as to flow the liquid LQ within the space SP1 in the collecting channel through the holes of the porous member 34 and prevent gas from passing therethrough. It should be noted that an example of the technique of collecting only the liquid through the porous member is disclosed in, for example, U.S. Pat. No. 7,292,313 and the like.

It should be noted that both the liquid LQ and the gas may be collected (suctioned) through the porous member 34. Further, the porous member 23 does not have to be provided.

In the present embodiment, while the liquid LQ from the supply port 31 is supplied, the liquid LQ from the collection port 33 is collected, thereby forming the liquid immersion space LS1 by the liquid LQ between the terminal optical element 13 and the first member 21 on one side and the substrate P on the other side. Further, in the present embodiment, the supply of the liquid LQ from the supply port 31 and the collection of the liquid LQ from the collection port 33 are performed in conjunction with the supply of the liquid LQ from the supply port 32. In the present embodiment, the liquid immersion space LS1 is formed by the liquid LQ which is supplied from the supply port 31. Further, in the present embodiment, the liquid immersion space LS1 is formed by the liquid LQ which is supplied from the supply port 32.

In the present embodiment, the lower surface 23 of the first member 21 includes: a lower surface 23B that is disposed around the opening 20 and does not collect the liquid LQ; and a lower surface 34B of the porous member 34 that is disposed around the lower surface 23B and is able to collect the liquid LQ. The liquid LQ cannot pass through the lower surface 23B. The lower surface 23B is able to hold the liquid LQ between itself and the substrate P.

In the present embodiment, the second member 22 includes: a supply port 35 that supplies the liquid LQ for forming the liquid immersion space LS2; and a collection port 36 that collects at least a part of the liquid LQ within the liquid immersion space LS2.

In the present embodiment, the supply port 35 can be opposed to the upper surface of the substrate P (object). The supply port 35 is disposed on at least a part of the lower surface 24 of the second member 22 so as to face the space SP2. In the present embodiment, the supply port 35 is able to supply the liquid LQ to the space SP2.

In the present embodiment, the collection port 36 can be opposed to the upper surface of the substrate P (object). The collection port 36 is disposed on at least a part of the lower surface 24 of the second member 22 so as to face the space SP2. In the present embodiment, the collection port 36 is able to collect the liquid LQ within the space SP2. Further, the collection port 36 is able to collect gas within the space SP2. In the present embodiment, the collection port 36 collects the liquid LQ together with the gas.

In the present embodiment, in relation to the direction of radiation to the optical path K, at least a part of the collection port 36 is disposed outside the first member 21. In the present embodiment, at least a part of the collection port 36 is disposed between the first member 21 and the supply port 35.

In the present embodiment, at least a part of the collection port 36 is disposed outside the supply port 35 relative to the first member 21. In the present embodiment, at least a part of the collection port 36 is disposed outside the supply port 35 in the direction of radiation to the optical path K.

In the present embodiment, the collection port 36 is disposed to enclose the supply port 35.

It should be noted that a plurality of collection ports 36 may be disposed around the supply port 35. That is, the plurality of collection ports 36 may be discretely disposed around the supply port 35.

The supply port 35 is connected to the liquid supply device, which is able to supply the liquid LQ, through the supply channel formed inside the second member 22. The supply port 35 supplies the liquid LQ from the liquid supply device to the space SP2.

At least a part of the fluid (one or both of the liquid LQ and the gas) within the space SP2 is collected from the collection port 36. Further, the collection port 36 of the second member 22 is able to collect the liquid LQ (the liquid LQ separated from the liquid immersion space LS1) from the space SP1 between the first member 21 and the object, together with the liquid LQ within the liquid immersion space LS2.

The collection port 36 is connected to the liquid collecting device, which is able to collect (suction) the liquid LQ, through the collecting channel formed inside the second member 22. Further, the collection port 36 is also able to collect the gas within the space SP2.

By supplying the liquid LQ from the supply port 35, the liquid immersion space LS2 is formed by the liquid LQ between the second member 22 on one side and the substrate P on the other side. That is, in the present embodiment, the liquid immersion space LS2 is formed by the liquid LQ supplied from the supply port 35. In the present embodiment, by collecting the liquid LQ from the collection port 36 while supplying the liquid LQ from the supply port 35, the liquid immersion space LS2 is formed.

It should be noted that, as shown in FIG. 6, a collection port (suctioning port) 500 capable of collecting (suctioning) the liquid LQ may be disposed at the outside edge of the first member 21. The outside edge of the first member 21 includes an outside region (portion) of the collection port 36 (porous member 34) relative to the optical path of the exposure light EL. In FIG. 6, the suctioning port 500 is disposed outside the collection port 36 (porous member 34) relative to the optical path of the exposure light EL. In the present embodiment, the outside edge of the first member 21 is formed by a porous member 501. Further, the side surface (outside surface) of the first member 21 is formed by the porous member 501. The collection port 500 includes holes of the porous member 501. The collection port 500 is connected to a vacuum system. The liquid LQ, which comes into contact with the outside edge of the first member 21 (porous member 501), is collected through the holes (collection port 500) of the porous member 501. It should be noted that the outside edge of the first member 21 may not be formed by the porous member 501. By disposing the collection port 500 at the outside edge of the first member 21, the liquid LQ, which flows out of the porous member 34 relative to the optical path of the exposure light EL, can be collected from the collection port 500.

It should be noted that the collection port 500 may not be connected to a vacuum system. By forming the outside edge of the first member 21 by the porous member 501, the liquid LQ, which flows out of the porous member 34 relative to the optical path of the exposure light EL, is absorbed by the porous member 501.

By disposing the collection port 500 (porous member 501) at the outside edge of the first member 21, the phenomenon (so-called bridge phenomenon) where the liquid LQ remains between the outside edge of the first member 21 and the object (such as the substrate F) is prevented from occurring. Further, it is also possible to collect (suction, absorb) the liquid LQ from the side surface (outside surface) of the first member 21.

Further, as shown in FIG. 6, a collection port (suctioning port) 600 capable of collecting (suctioning) the liquid LQ may be provided at the inside edge of the second member 22, and the inside edge of the second member 22 may be formed by a porous member 601. Further, as shown in FIG. 6, a collection port (suctioning port) 700 capable of collecting (suctioning) the liquid LQ may be provided at the outside edge of the second member 22, and the outside edge of the second member 22 may be formed by a porous member 701. The inside surface of the second member 22 is formed by the porous member 601. The outside surface of the second member 22 is formed by the porous member 701. Thereby, the phenomenon (so-called bridge phenomenon) where the liquid LQ remains between the inside edge of the second member 22 and the object (such as the substrate P) or between the outside edge of the second member 22 and the object (such as the substrate F) is prevented from occurring. Further, it is also possible to collect (suction, absorb) the liquid LQ from the side surfaces (the inside surface, the outside surface) of the second member 22.

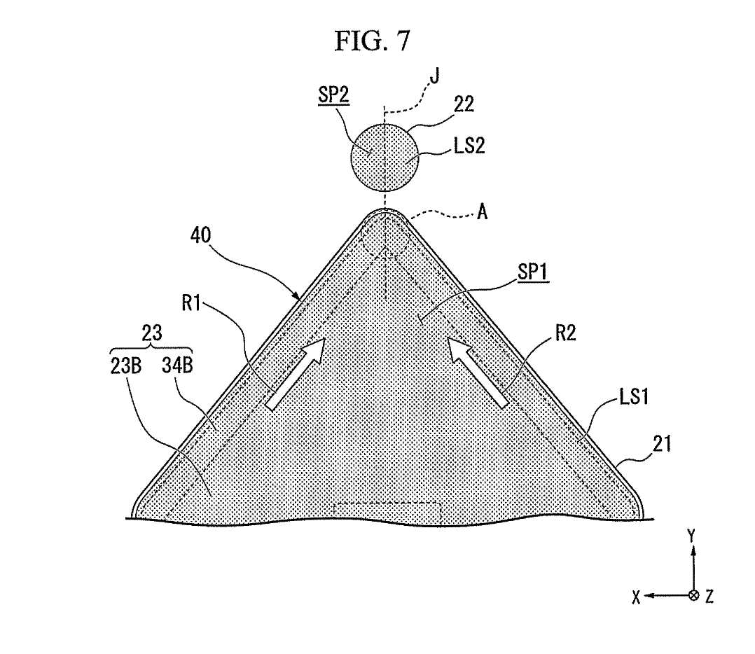

FIG. 7 is a schematic diagram of the first member 21, the second member 22, a part of the liquid immersion space LS1, and the liquid immersion space LS2 as viewed from the lower side.

In the present embodiment, the second member 22 on the +Y side of the first member 21 and the second member 22 on the −Y side have substantially the same structure. In the following description, mainly, the second member 22 on the +Y side of the first member 21 and the liquid immersion space LS2 will be described.

In the present embodiment, the liquid immersion member 5 has a guiding section 40 that guides at least a part of the liquid LQ within the liquid immersion space LS1 into a guiding space A which is a part of a space at the surrounding of the optical path K. The liquid immersion space LS2 is formed adjacent to the guiding space A.

In the present embodiment, the guiding space A includes a partial space (a part) of the space SP1 between the lower surface 23 of the first member 21 and the upper surface of the object (such as the substrate P) opposed to the lower surface 23. In the present embodiment, the guiding space A includes a space between the substrate P and a part of the peripheral portion (the peripheral portion of the lower surface 23) of the first member 21.

In the present embodiment, the guiding space A is defined between the liquid immersion space LS2 and the optical path K. In the present embodiment, at least apart of the second member 22 is disposed adjacent to the guiding space A. The second member 22 is disposed near the guiding space A so as to be adjacent to the guiding space A outside the guiding space A relative to the optical path K. The guiding space A is formed to include, for example, a virtual line connecting the optical path K and the liquid immersion space LS2 (second member 22).

It should be noted that the guiding space A may not be a space between the substrate P (object) and a part of the peripheral portion of the lower surface 23. For example, the guiding space A may be a space between the substrate P (object) and a part of the inside region of the peripheral portion of the lower surface 23. For example, the guiding space A may be a space between the substrate P (object) and a part of the central portion of the lower surface 23. Further, the guiding space A may include a space outside the space SP1 between the substrate P (object) and the lower surface 23. For example, the guiding space A may include at least a part of the space SP2 between the upper surface of the substrate P (object) and the lower surface 24 of the second member 22. Further, the guiding space A may include a space under the gap between the inside surface of the second member 22 and the outside surface of the first member 21.

In the present embodiment, at least a part of the guiding section 40 is disposed on the first member 21. In the present embodiment, at least a part of the guiding section 40 is disposed on the lower surface 23 of the first member 21 which can be opposed to the substrate P (object). The guiding section 40 may guide at least a part of the liquid LQ within the liquid immersion space LS1 between the substrate P (object) and the lower surface 23 into the guiding space A.

In the present embodiment, the guiding section 40 may include, for example, the edge of the first member 21. The edge of the first member 21 is able to guide at least a part of the liquid LQ within the liquid immersion space LS1 into the guiding space A.

At least a part of the liquid LQ within the liquid immersion space LS1 is guided by the edge of the first member 21, and flows toward the guiding space A.

Further, in the present embodiment, the guiding section 40 includes, for example, at least a part of the lower surface 34B of the porous member 34. The lower surface 34B is able to guide at least a part of the liquid LQ within the liquid immersion space LS1 into the guiding space A.

At least a part of the liquid LQ within the liquid immersion space LS1 is guided by the lower surface 34B of the porous member 34, and flows toward the guiding space A.

Further, in the present embodiment, the guiding section 40 includes, for example, the boundary between the lower surface 34B and the lower surface 23B. In the present embodiment, the state (surface state) of the lower surface 34B and the state (surface state) of the lower surface 23B are different. The lower surface 34B is disposed around the lower end of the holes of the porous member 34. The lower surface 34B is uneven. It should be noted that the angle of contact with the liquid LQ may be different between the lower surface 34B and the lower surface 23B.

The boundary between the lower surface 34B and the lower surface 23B is able to guide at least a part of the liquid LQ within the liquid immersion space LS1 into the guiding space A. It should be noted that the heights of the lower surface 34B and the lower surface 23B may be different. That is the boundary between the lower surface 34B and the lower surface 23B may have different levels.

At least a part of the liquid LQ within the liquid immersion space LS1 is guided into the boundary between the lower surface 34B and the lower surface 23B, and flows toward the guiding space A.

In the present embodiment, at least a part of the edge of the lower surface 23 linearly extends toward the guiding space A.

Further, in the present embodiment, at least a part of the lower surface 34B of the porous member 34 extends in a band shape toward the guiding space A.

Further, in the present embodiment, at least a part of the boundary between the lower surface 34B and the lower surface 23B linearly extends toward the guiding space A.

In the present embodiment, a part of the edge of the lower surface 23 is disposed to extend toward the guiding space A from the +X side of the axis J passing through the space SP2 in the plane (in the XY plane) which is substantially parallel to the upper surface of the substrate P (object). Further, apart of the edge of the lower surface 23 is disposed to extend toward the guiding space A from the −X side of the axis J passing through the space SP2 in the plane (in the XY plane) which is substantially parallel to the upper surface of the substrate P (object).

The axis 3 includes the virtual axis (the virtual line) passing through the space SP2. The axis 1 passing through the space SP2 passes through the liquid immersion space LS2. The axis 7 connects the optical path K and the space SP2 (the liquid immersion space LS2) in the XY plane. The axis J connects, for example, the optical path K and the center of the space SP2 (the liquid immersion space LS2) in the X axis direction. In the present embodiment, the axis J passes the center of the opening 20, and is substantially parallel to the Y axis.

In the present embodiment, a part of the lower surface 34B is disposed to extend toward the guiding space A from the +X side of the axis 3, in the plane (in the XY plane) which is substantially parallel to the upper surface of the substrate P (object). A part of the lower surface 34B is disposed to extend toward the guiding space A from the −X side of the axis 3, in the plane (in the XY plane) which is substantially parallel to the upper surface of the substrate P (object).

In the present embodiment, a part of the boundary between the lower surface 34B and the lower surface 23B is disposed to extend toward the guiding space A from the +X side of the axis 3, in the plane (in the XY plane) which is substantially parallel to the upper surface of the substrate P (object). Further, a part of the boundary between the lower surface 34B and the lower surface 23B is disposed to extend toward the guiding space A from the −X side of the axis 3, in the plane (in the XY plane) which is substantially parallel to the upper surface of the substrate P (object).

In the present embodiment, the axis J passes through the supply port 35. Further, in the present embodiment, the axis J passes through the collection port 36.

In the present embodiment, each second member 22 captures at least a part of the liquid LQ, which flows from the space SP1 through the guiding section 40, in the liquid immersion space LS2.

It should be noted that the guiding section 40 may not be disposed on the first member 21. For example, the guiding section 40 may include a gas supply portion that is disposed outside the first member 21 and supplies gas to at least a part of the liquid immersion space LS1. At least a part of the liquid LQ within the liquid immersion space LS1 is guided into the guiding space A by the gas supplied from the gas supply portion.

Next, a description will be given of a method of exposing the substrate P by using the exposure apparatus EX which has the above-mentioned configuration.

In order to carry (load) the unexposed substrate P in the first holding section 16, the control device 6 moves the substrate stage 2 to a position for exchanging the substrates separated from the liquid immersion member 5. In addition, for example, when the exposed substrate P is held by the first holding section 16, the process of carrying (unloading) the exposed substrate P out from the first holding section 16 is performed, and thereafter the process of carrying (loading) the unexposed substrate P in the first holding section 16 is performed.

The substrate exchange position is a position at which the process of exchanging the substrate P can be executed. The process of exchanging the substrate P includes at least one of a process of carrying (unloading) the exposed substrate P, which is held by the first holding section 16, out from the first holding section 16 by using the conveying device and a process of carrying (loading) the unexposed substrate P in the first holding section 16. The control device 6 performs the process of exchanging the substrate P by moving the substrate stage 2 to the substrate exchange position separated from the liquid immersion member 5.

In at least a part of the period during which the substrate stage 2 is separated from the liquid immersion member 5, the measurement stage 3 is disposed to be opposed to the lower surfaces 23 and 24 of the liquid immersion member 5 and the emission surface 12 of the terminal optical element 13. In a state where the measurement stage 3 is disposed to be opposed to the emission surface 12 and the lower surfaces 23 and 24, the liquid immersion space LS1 of the liquid LQ is formed on the emission surface 12 side. By collecting the liquid LQ from the collection port 33 while supplying the liquid LQ from the supply ports 31 and 32, the liquid immersion space LS1 is formed on at least a part of the optical path space SPK and the first space SP1.

Further, the control device 6 causes the second members 22 to form the liquid immersion spaces LS2 of the liquid LQ the part of the surrounding of the liquid immersion space LS1. The control device 6 forms the liquid immersion spaces LS2 by collecting the liquid LQ from the collection port 36 while supplying the liquid LQ from the supply port 35.

Furthermore, in at least a part of the period during which the substrate stage 2 is separated from the liquid immersion member 5, a measurement process using a measurement member (measurement instrument) C mounted on the measurement stage 3 is performed as necessary. When performing the measurement process using the measurement member (measurement instrument) C, the control device 6 forms the liquid immersion space LS1 such that the optical path K between the terminal optical element 13 and the measurement member C is filled with the liquid LQ. The control device 6 irradiates the measurement member C with the exposure light EL through the projection optical system PL and the liquid LQ, and performs the measurement proms using the measurement member C. The result of the measurement process is reflected in the process of exposing the substrate P.

After the unexposed substrate P is loaded on the first holding section 16 and the measurement process using the measurement member (measurement instrument) C is terminated, the control device 6 removes the measurement stage 3 from the position opposed to the emission surface 12 and the lower surfaces 23 and 24, and moves the substrate stage 2 which holds the substrate P at the position opposed to the emission surface 12 and lower surfaces 23 and 24. In the present embodiment, for example, as disclosed in US Patent Application, Publication No. 2006/0023186 and US Patent Application, Publication No. 2007/0127006, the control device 6 moves the substrate stage 2 and the measurement stage 3 in the XY plane relative to the terminal optical element 13 and the liquid immersion member 5, while opposing the terminal optical element 13 and the liquid immersion member 5, to at least one of the substrate stage 2 and the measurement stage 3 in a state where the upper surface of the substrate stage 2 is set to be close to or in contact with the upper surface of the measurement stage 3 such that the liquid immersion space LS1 of the liquid LQ is continuously formed between the terminal optical element 13 and the liquid immersion member 5 (first member 21) and at least one of the substrate stage 2 and the measurement stage 3. Further, in the present embodiment, the control device 6 moves the substrate stage 2 and the measurement stage 3 in the XY plane relative to the terminal optical element 13 and the liquid immersion member 5 while opposing the terminal optical element 13 and the liquid immersion member 5 to at least one of the substrate stage 2 and the measurement stage 3 in a state where the upper surface of the substrate stage 2 is set to be close to or in contact with the upper surface of the measurement stage 3 such that the liquid immersion spaces LS2 of the liquid LQ are continuously formed between the terminal optical element 13 and at least one of the substrate stage 2 and the measurement stage 3 and between the liquid immersion member 5 (second members 22) and at least one of the substrate stage 2 and the measurement stage 3. Thereby, while the leakage of the liquid LQ is suppressed, a state where the liquid immersion spaces LS1 and LS2 are formed between the measurement stage 3 and the terminal optical element 13 and between the measurement stage 3 and the liquid immersion member 5 is changed to a state where the spaces are formed between the substrate stage 2 and the terminal optical element 13 and between the substrate stage 2 and the liquid immersion member 5. Further, the control device 6 may change the state where the liquid immersion spaces LS1 and LS2 are formed between the measurement stage 3 and the terminal optical element 13 and between the measurement stage 3 and the liquid immersion member 5, to the state where the spaces are formed between the substrate stage 2 and the terminal optical element 13 and between the substrate stage 2 and the liquid immersion member 5.

In the following description, the operation, which synchronously moves the substrate stage 2 and the measurement stage 3 in the XY plane relative to the terminal optical element 13 and the liquid immersion member 5 in the state where the upper surface of the substrate stage 2 is set to be close to or in contact with the upper surface of the measurement stage 3, is simply referred to as a scrum movement operation.

The substrate stage 2, which holds the substrate P, is disposed to be opposed to the lower surfaces 23 and 24 of the liquid immersion member 5 and the emission surface 12 of the terminal optical element 13, through the serum movement operation. The control device 6 forms the liquid immersion space LS1 of the liquid LQ on the emission surface 12 side in a state where the substrate P (substrate stage 2) is disposed to be opposed to the emission surface 12 and the lower surfaces 23 and 24. By collecting the liquid LQ from the collection port 33 while supplying the liquid LQ from the supply ports 31 and 32, the liquid immersion space LS1 is formed on at least a part of the optical path space SPK and the first space SP1. Further, the control device 6 forms the liquid immersion spaces LS2 at least the part of the surrounding of the liquid immersion space LS1. By collecting the liquid LQ from the collection port 36 while supplying the liquid LQ from the supply port 35, each liquid immersion space LS2 is formed on at least apart of the second space SP2.

The control device 6 starts the process of exposing the substrate P. The control device 6 emits the exposure light EL from the illumination system IL in the state where the liquid immersion spaces LS1 and LS2 are formed on the substrate P. The illumination system IL illuminates the mask M with the exposure light EL. The exposure light EL from the mask M is illuminated on the substrate P through the liquid LQ within the liquid immersion space LS1 between the substrate P and each of the projection optical system PL and the emission surface 12. Thereby, the substrate P is exposed to the exposure light EL, which is emitted from the emission surface 12, through the liquid LQ within the liquid immersion space LS1, and an image of the pattern of the mask M is projected onto the substrate P.

In the present embodiment, the exposure apparatus EX is a scanning type exposure apparatus (a so-called scanning stepper) that projects the image of the pattern of the mask M onto the substrate P while synchronously moving the mask M and the substrate P in predetermined scanning directions. In the present embodiment, the scanning direction (the synchronous movement direction) of the substrate P is set to the Y axis direction, and the scanning direction (the synchronous movement direction) of the mask M is also set to the Y axis direction. The control device 6 moves the substrate P in the Y axis direction relative to the projection region PR of the projection optical system PL, and moves the mask M in the Y axis direction relative to the illumination region IR of the illumination system IL, in synchronization with the movement of the substrate P in the Y axis direction. Meanwhile, the control device 6 irradiates the substrate P with the exposure light EL through the projection optical system PL and the liquid LQ in the liquid immersion space LS1 above the substrate P.

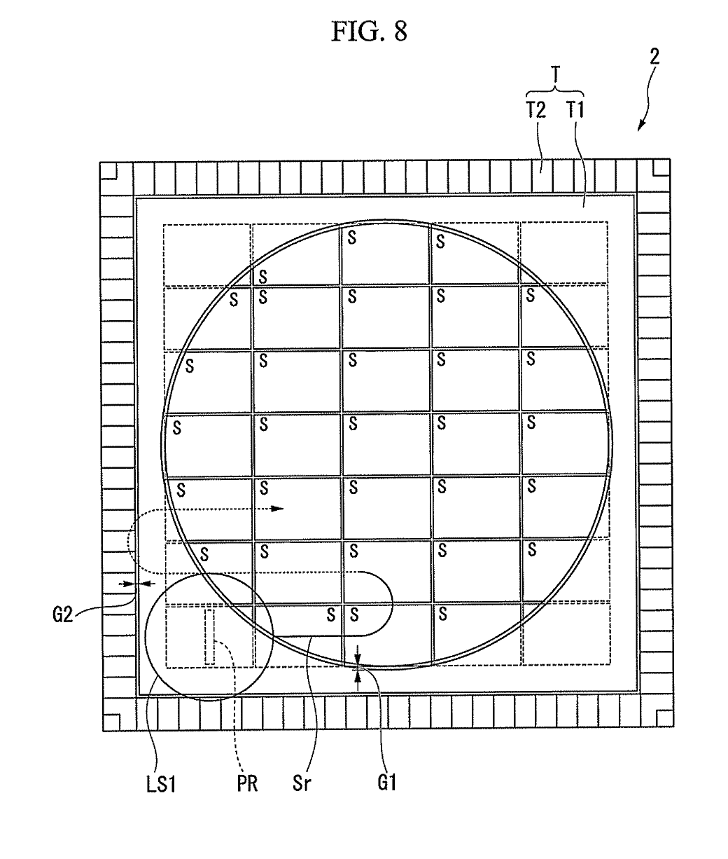

FIG. 8 is a diagram illustrating an example of the substrate P which is held by the substrate stage 2. In the present embodiment, a plurality of shot regions 5, which are exposure target regions, are disposed in a matrix on the substrate P. The control device 6 sequentially exposes the plurality of shot regions S of the substrate P, which are held by the first holding section 16, to the exposure light EL through the liquid LQ within the liquid immersion space LS1.

For example, in order to expose the first shot region S of the substrate P, in the state where the liquid immersion spaces LS1 and LS2 are formed, the control device 6 moves the substrate P (first shot region S) in the Y axis direction relative to the projection region PR of the projection optical system PL, and moves the mask M in the Y axis direction relative to the illumination region IR of the illumination system IL, in synchronization with the movement of the substrate P in the Y axis direction. Meanwhile, the control device 6 irradiates the first shot region S with the exposure light EL through the liquid LQ within the liquid immersion space LS1 on the substrate P and the projection optical system PL. Thereby, the image of the pattern of the mask M is projected onto the first shot region S of the substrate P, and the first shot region S is exposed to the exposure light EL which is emitted from the emission surface 12. After the exposure of the first shot region S is terminated, in order to start the subsequent exposure of the second shot region S, in the state where the liquid immersion spaces LS1 and LS2 are formed, the control device 6 moves the substrate P in a direction (for example, the X axis direction, a direction tilted with respect to the X axis and Y axis directions in the XY plane, or the like) orthogonal to the X axis in the XY plane, and moves the second shot region S to the exposure start position. Thereafter, the control device 6 starts the exposure of the second shot region S.

The control device 6 sequentially exposes the plurality of shot regions of the substrate P while repeating the following operations; an operation that exposes the shot region while moving the shot region in the Y axis direction relative to the position (projection region PR) irradiated with the exposure light EL from the emission surface 12 in the state where the liquid immersion spaces LS1 and LS2 are formed on the substrate P (substrate stage 2); and an operation that, after the exposure of the shot region, moves the substrate P in a direction (for example, the X axis direction, a direction tilted with respect to the X axis and axis directions in the XY plane, or the like) orthogonal to the Y axis direction in the XY plane such that the next shot region is disposed at the exposure start position in the state where the liquid immersion spaces LS1 and LS2 are formed on the substrate P (substrate stage 2).

In the following description, in order to expose the shot region, in the state where the liquid immersion spaces LS1 and LS2 are formed on the substrate (substrate stage 2), the substrate P (shot region) is moved in the Y axis direction relative to the position (projection region PR) irradiated with the exposure light EL from the emission surface 12. This operation is simply referred to as a scanning movement operation. Further, after the exposure of a certain shot region, in order to expose the next shot region, in the state where the liquid immersion spaces LS1 and LS2 are formed on the substrate P (substrate stage 2), the substrate P is moved in the direction orthogonal to the Y axis direction in the XY plane such that the next shot region is disposed at the exposure start position. This operation is simply referred to as a stepping movement operation. While the scanning movement operation and the stepping movement operation is repeated, the plurality of shot regions S of the substrate P are sequentially exposed. It should be noted that the scanning movement operation is exclusively movement in the Y axis direction at a constant velocity. Further, the stepping movement operation includes acceleration or deceleration movement. For example, the stepping movement operation between two shot regions, which are adjacent in the X axis direction, includes acceleration or deceleration movement in the Y axis direction and acceleration or deceleration movement in the X axis direction.

In the present embodiment, the liquid immersion spaces LS2 are continuously formed the part aft surrounding of the liquid immersion space LS1 during the scanning movement operation. Further, in the present embodiment, the liquid immersion spaces LS2 are continuously formed the part of the surrounding of the liquid immersion space LS1 during the stepping movement operation.

In addition, in the following description, during the scanning movement operation and the stepping movement operation, the liquid immersion spaces LS1 and LS2 are formed on the substrate P. However, during at least a part of the scanning movement operation and the stepping movement operation, at least a part of the liquid immersion spaces LS1 and LS2 is likely to be formed on the substrate stage 2 (enclosing member T).

The control device 6 controls the driving system 15 based on the exposure condition of the plurality of shot regions S on the substrate P, and moves the substrate P (substrate stage 2). The exposure condition of the plurality of shot regions S are defined by, for example, exposure control information which is called an exposure recipe. The exposure control information is stored in a storage device 7. The control device 6 sequential exposes the plurality of shot regions S while moving the substrate P in a predetermined movement condition, based on the exposure condition which is stored in the storage device 7. The movement condition of the substrate P (object) includes at least one movement locus in the XY plane relative to the movement velocity, the acceleration, the movement distance, the movement direction of the substrate P (object), and the optical path K (the liquid immersion spaces LS1 and LS2).

In the present embodiment, the control device 6 irradiates the projection region PR with the exposure light EL while moving the substrate stage 2 such that the substrate P and the projection region PR of the projection optical system PL are relatively moved along the movement locus indicated by the arrow Sr of FIG. 8, and sequentially exposes the plurality of shot regions S of the substrate P with the exposure light EL through the liquid LQ.

Hereinafter, the plurality of substrates P are sequentially exposed by repeating the above-mentioned process.

As described above, in the present embodiment, there is provided a guiding section 40 that guides at least a part of the liquid LQ, which forms the liquid immersion space LS1, into the guiding space A. Consequently, when the object such as the substrate P is moved in the Y axis direction parallel to the axis 7 in the state where the liquid immersion space LS1 is formed, at least a part of the liquid LQ within the liquid immersion space LS1 is guided into the guiding space A.

For example, as shown in FIG. 7, when the object is moved in the +Y direction, at least a part of the liquid LQ, which forms the liquid immersion space LS1, flows in the space SP1 due to the movement of the object. At least a part of the liquid LQ, which flows by the movement of the object in the +Y direction and forms the liquid immersion space LS1, flows in directions indicated by, for example, arrows R1 and R2, and is guided into the guiding space A which is adjacent to the liquid immersion space LS2, due to the guiding section 40.

It should be noted that the guiding section 40 is able to guide the liquid LQ into the guiding space A even when the object is moved in a direction different from the +Y direction. That is, when the object is moved in a direction including a component of the +Y direction, the guiding section 40 is able to guide the liquid LQ into the guiding space A. For example, when the object is moved in the +X direction while being moved in the +Y direction, the guiding section 40 is able to guide the liquid LQ into the guiding space A. Further, when the object is moved in the −X direction while being moved in the +Y direction, the guiding section 40 is able to guide the liquid LQ into the guiding space A. As described above, the guiding section 40 is able to guide at least a part of the liquid LQ, which flows by the movement of the object including the movement in the +Y direction and forms the liquid immersion space LS1, into the guiding space A.

Likewise, when the object is moved in the −Y direction, or when the object is moved in a direction including the component of the −Y direction, the guiding section 40 is able to guide at least a part of the liquid LQ, which forms the liquid immersion space LS1, into the guiding space A which is adjacent to the liquid immersion space LS2 on the side of the first member 21.

In a predetermined operation of the exposure apparatus EX, when the object is moved in the predetermined movement condition in the state where the liquid immersion space LS1 is formed, at least a part of the liquid LQ within the liquid immersion space LS1 is likely to flow out of the space SP1.

For example, in the scrum movement operation of the exposure apparatus EX, at least a part of the liquid LQ within the liquid immersion space LS1 is likely to flow out of the space SP1.

Further, for example, in the scanning movement operation of the exposure apparatus EX, at least a part of the liquid LQ within the liquid immersion space LS1 is likely to flow out of the space SP1.

Furthermore, in the stepping movement operation of the exposure apparatus EX, at least a part of the liquid LQ within the liquid immersion space LS1 is likely to flow out of the space SP1.

For example, in at least one predetermined operation of the scrum movement operation, the scanning movement operation, and the stepping movement operation, the object is likely to be moved in the Y axis direction under a condition that does not satisfy a predetermined admissibility condition capable of holding the liquid immersion space LS1 of the liquid LQ between the first member 21 and the object.

For example, in the predetermined operation, the object is likely to be moved in the Y axis direction by a distance longer than a predetermined allowable distance capable of holding the liquid immersion space LS1 of the liquid LQ between the first member 21 and the object.

Further, in the predetermined operation, the object is likely to be moved in the Y axis direction at a velocity higher than a predetermined allowable velocity capable of holding the liquid immersion space LS1 of the liquid LQ between the first member 21 and the object.

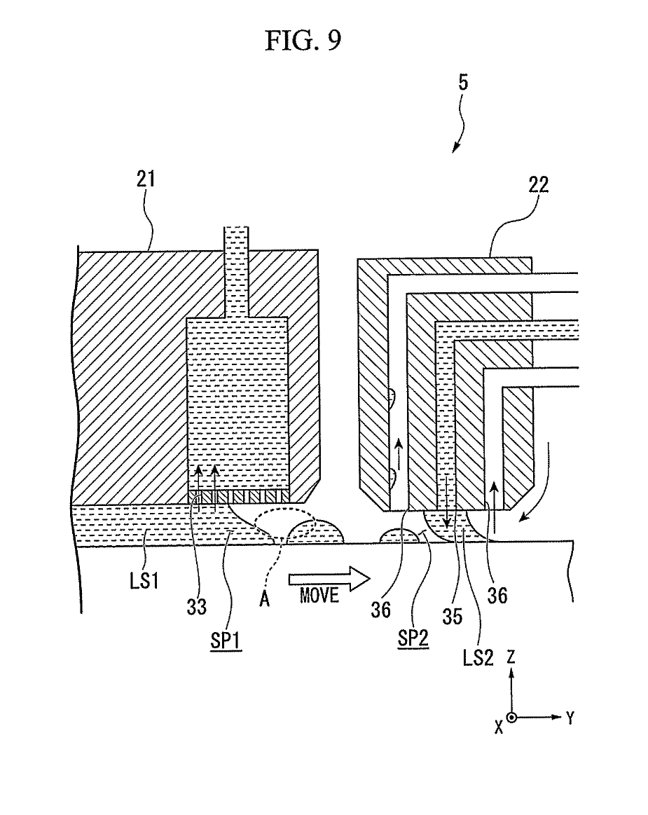

FIG. 9 is a diagram schematically illustrating an example of a state where the object such as the substrate P is moved in the Y axis direction under a condition that does not satisfy a predetermined admissibility condition capable of holding the liquid immersion space LS1 of the liquid LQ between the first member 21 and the object.

As shown in FIG. 9, for example, when the object is moved in the Y axis direction under the condition that does not satisfy the admissibility condition, at least a part of the liquid LQ within the liquid immersion space LS1 is likely to flow out of the space SP1.

In the present embodiment, when the object is moved in the +Y direction, the liquid LQ within the liquid immersion space LS1 is guided into the guiding space A by the guiding section 40. Accordingly, when the object is moved in the +Y direction under the condition that does not satisfy the admissibility condition, after the liquid LQ within the liquid immersion space LS1 is collected in the guiding space A, the liquid is highly likely to flow out of the space SP1 from the guiding space A. That is, at least a part of the liquid LQ within the space SP1 is highly likely to flow out of the space SP1 through the guiding space A. In other words, when the object is moved in the +Y direction, after the liquid LQ within the liquid immersion space LS1 is collected in the guiding space A, the liquid is highly likely to flow out to the +Y side of the guiding space A.

In the present embodiment, the liquid immersion space LS2 of the liquid LQ is formed by the second members 22 so as to be adjacent to the guiding space A. In the present embodiment, the second members 22 are disposed adjacent to the first member 21 in the Y axis direction in which the object is moved in the predetermined operation of the exposure apparatus EX. The liquid immersion space LS2 is disposed adjacent to the guiding space A on the +Y side of the guiding space A.

Consequently, the liquid LQ, which flows out of the space SP1 through the guiding space A, is moved toward the liquid immersion space LS2. Thereby, the liquid LQ, which flows out of the space SP1, is captured by the liquid immersion space LS2, and is inhibited from flowing out of the space SP2.

That is, in the present embodiment, the liquid immersion space LS2 is unable to collect all the liquid through the collection port 33, and stops the liquid LQ, which leaks out from the space SP1, from flowing out. For example, the liquid LQ, which flows out of the space SP1, joins the liquid LQ within the liquid immersion space LS2 in the space SP2. Further, the liquid LQ, which flows out of the space SP1, is collected from, for example, the collection port 36 between the first member 21 and the supply port 35. The collection port 36 collects the liquid LQ, which flows out from the space SP1, together with the liquid LQ within the liquid immersion space LS2.

In the present embodiment, the liquid immersion space LS2 is smaller than the liquid immersion space LS1. Hence, even when the object is moved in the Y axis direction under the condition that does not satisfy the predetermined admissibility condition capable of holding the liquid immersion space LS1 of the liquid LQ in the space SP1, the liquid LQ within the liquid immersion space LS2 is inhibited from flowing out from the space SP2.

Further, in the present embodiment, the second members 22 are movable in a state where the liquid immersion spaces LS2 are formed to be separated from the liquid immersion space LS1.

In the present embodiment, each second member 22 is moved to track the object (such as the substrate P) opposed thereto in at least a part of the periphery of the first member 21. The second member 22 is movable in the XY plane so as to track the object (such as the substrate P) which is moved in the XY plane.

Further, in the present embodiment, each second member 22 is moved such that the relative movement between itself and the object (such as the substrate P) opposed thereto decreases. The second member 22 is moved such that the relative movement between itself and the object (such as the substrate P) opposed thereto is less than the relative movement between the first member 21 and the object (such as the substrate P). The second member 22 is movable such that the relative movement between itself and the object (such as the substrate P), which is moved in the XY plane, is less than the relative movement between the first member 21 and the object (such as the substrate P).

The relative movement includes at least a part of the relative velocity and the relative acceleration. For example, the second member 22 is moved such that the relative velocity between itself and the object (such as the substrate P) decreases. Further, for example, the second member 22 is moved such that the relative acceleration to the object (such as the substrate P) decreases.

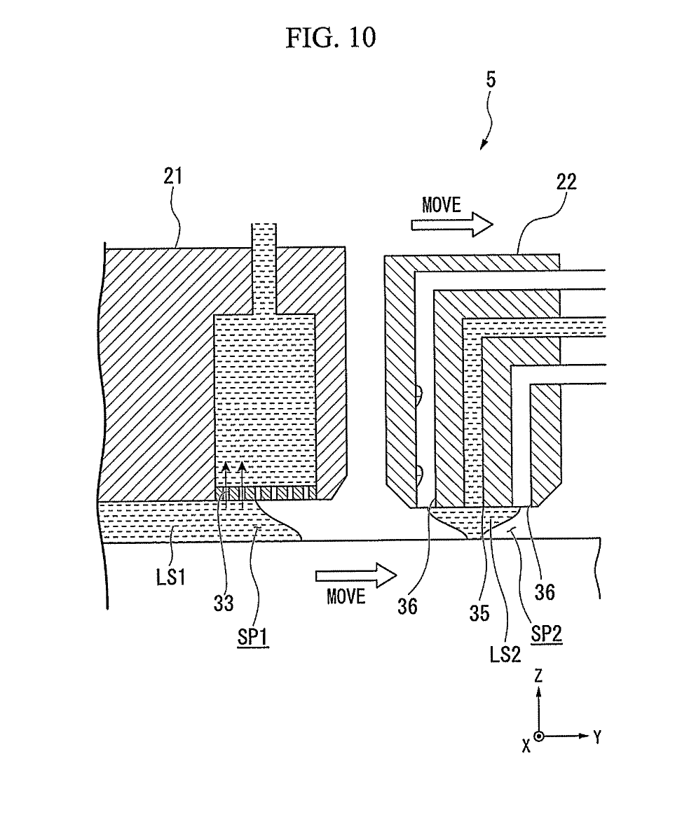

FIG. 10 is a diagram illustrating an example of the operation of the second member 22. The position of the terminal optical element 13 is substantially fixed. In the present embodiment, the position of the first member 21 is substantially fixed. In other words, the relative position of the first member 21 to the terminal optical element 13 is substantially not changed. In contrast, the position of the second member 22 is changed. In other words, the relative position of the second member 22 to the terminal optical element 13 is changed.

For example, as shown in FIG. 10, when the substrate P (object) is moved in the +Y direction, the second member 22 is moved in the +Y direction so as to track the substrate P in the state where the liquid immersion space LS2 is formed. That is, in the present embodiment, in the state where the liquid immersion space LS2 is formed, the substrate P, which comes into contact with the liquid LQ within the liquid immersion space LS2, is moved in the +Y direction relative to the second member 22, whereby the second member 22 is moved in the +Y direction. Further, when substrate P is moved at the velocity Vpy, the second member 22 is moved such that the relative velocity between itself and the substrate P decreases in the state where the liquid immersion space LS2 is formed. Furthermore, when the substrate P is moved at the acceleration Apy, the second member 22 is moved such that the relative acceleration between itself and the substrate P decreases in the state where the liquid immersion space LS2 is formed.

The second member 22 is moved such that the relative velocity between itself and the object (such as the substrate P) decreases. Hence, the liquid immersion space LS2 (the interface LG2 of the liquid LQ within the liquid immersion space LS2) is held. That is, it is difficult to thin the liquid LQ which forms the liquid immersion space LS2, and thus the liquid LQ within the liquid immersion space LS2 is inhibited from flowing out from the space SP2.

It should be noted that FIG. 10 shows a case where the substrate P is moved in the Y axis direction (+Y direction). When the substrate P is moved in the −Y direction, the second member 22 is movable in the −Y direction so as to track the substrate P. Further, when the substrate P is moved in the +X direction, the second member 22 is movable in the +X direction so as to track the substrate P. Furthermore, when the substrate P is moved in the −X direction, the second member 22 is movable in the −X direction so as to track the substrate P. In addition, when the substrate P is moved in a direction orthogonal to the X axis and Y axis directions in the XY plane, the second member 22 is movable in the XY plane in the direction orthogonal to the X axis and Y axis directions so as to track the substrate P.

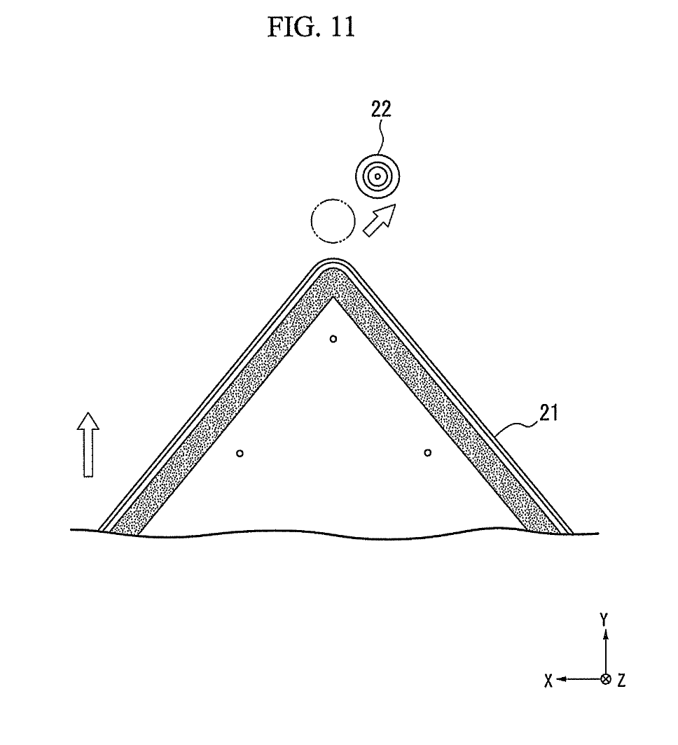

It should be noted that the second member 22 may not be moved in the same direction as the object (such as the substrate P). For example, when the substrate P is moved in the +Y direction, as shown in FIG. 11, the second member 22 may be moved in the +Y direction while being moved in the −X direction, and may be moved in the +Y direction while being moved in the +X direction. That is, for example, when the substrate P is moved in the +Y direction, the second member 22 may be moved in a direction including the component of the +Y direction. With such a configuration, the relative movement (relative velocity, relative acceleration) between the second member 22 and the substrate P also decreases.

Further, when substrate P is moved at the velocity Vp in the XY plane, the second member 22 is movable in the XY plane such that the relative velocity between itself and the substrate P is less than the relative velocity between the first member 21 and the substrate P, in the state where the liquid immersion space LS2 is formed. Furthermore, when the substrate P is moved at with the acceleration Ap in the XY plane, the second member 22 is movable in the XY plane such that the relative acceleration between itself and the substrate P is less than the relative acceleration between the first member 21 and the substrate P, in the state where the liquid immersion space LS2 is formed.

As described above, the substrate P (substrate stage 2) is moved by the driving system 15. The second member 22 is moved by the driving system 30. In the present embodiment, the control device 6 controls the driving system 30 based on the control information of the driving system 15. The control information of the driving system 15 includes at least one of the movement velocity, the acceleration, the movement distance, the movement direction, and the movement locus of the substrate P (substrate stage 2).

In the present embodiment, the control device 6 controls the driving system 30 based on the control information of the driving system 15 such that the second member 22 tracks the substrate P (substrate stage 2).

Further, the control device 6 may control the driving system 30 based on the control information of the driving system 15 so as to decrease the relative velocity between the second member 22 and the substrate P (substrate stage 2).

Furthermore, the control device 6 may control the driving system 30 based on the control information of the driving system 15 so as to decrease the relative acceleration between the second member 22 and the substrate P (substrate stage 2).

It should be noted that the control device 6 may control the driving system 30 based on the measurement result of the measurement system 4. From the measurement result of the measurement system 4, it is possible to acquire at least one of the position, the movement velocity, the acceleration, the movement direction, and the movement locus of the substrate P (substrate stage 2).

For example, the control device 6 acquires at least one of the position, the movement velocity, the acceleration, the movement direction, and the movement locus of the substrate P (substrate stage 2) by using the measurement system 4. Based on the result, the control device 6 may control the driving system 30 such that the second member 22 tracks the substrate P (substrate stage 2).

Further, the control device 6 may control the driving system 30 so as to decrease the relative velocity between the second member 22 and the substrate P (substrate stage 2), based on the measurement result of the measurement system 4.

Furthermore, the control device 6 may control the driving system 30 so as to decrease the relative acceleration between the second member 22 and the substrate P (substrate stage 2), based on the measurement result of the measurement system 4.

As described above, in the present embodiment, in at least apart of the periphery of the liquid immersion space LS1, the second member 22, which forms the liquid immersion space LS2 separated from the liquid immersion space LS1, is provided. Therefore, even when the liquid LQ flows out from the space SP1, the liquid LQ, which flows out, can be captured in the liquid immersion space LS2. Further, the second member 22 is moved such that the relative movement between itself and the object opposed thereto decreases in the state where the liquid immersion space LS2 is formed. Hence, the liquid LQ is inhibited from flowing out from the space SP2. Consequently, occurrence of the exposure defects and production of defective devices can be suppressed.

### Second Embodiment

Next, the second embodiment will be described. In the following description, components the same as or equivalent to those of the above-mentioned embodiment are represented by the same reference signs, and a description thereof will be simplified or omitted here.

In the present embodiment, the second member 22 is moved to a position at which the liquid LQ flowing out from the space SP1 is easily captured in the liquid immersion space LS2.

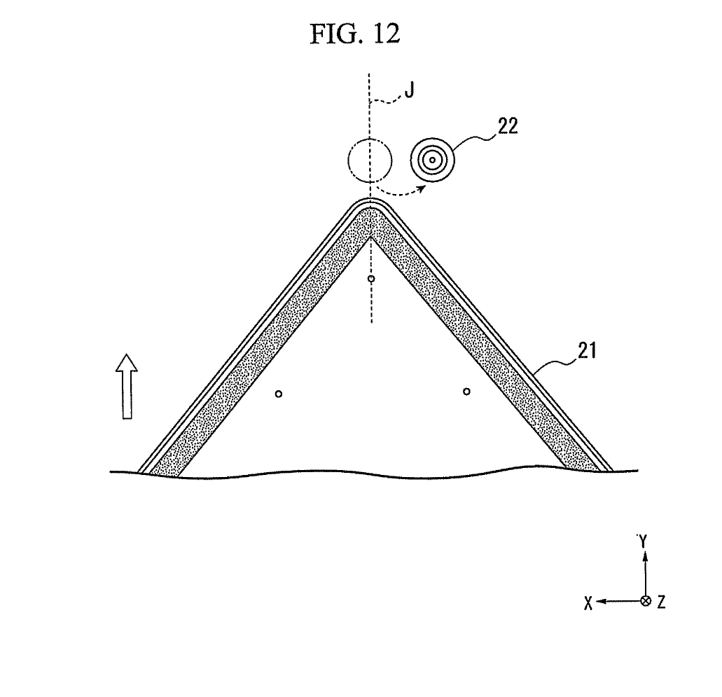

In the above-mentioned first embodiment, the liquid immersion space LS is formed on the axis 1 parallel to the Y axis which passes through the center of the opening 20 of the first member 21. However, for example, as shown in FIG. 12, when the liquid immersion space LS2 is disposed at the position separated from the axis J, it may be easier to capture the liquid LQ, which flows out from the liquid immersion space LS1, in the liquid immersion space LS2. The position, at which the liquid LQ is highly likely to flow out from the space SP1, can be estimated from the movement condition of the object or the like. In the present embodiment, the control device 6 moves the second member 22 to the position, at which the liquid LQ flowing out from the liquid immersion space LS1 is easily captured in the liquid immersion space LS2, before the exposure of the substrate P.

Further, in the present embodiment, in a similar manner to the first embodiment, the second member 22 is moved such that the relative movement between itself and the object (substrate P) opposed thereto decreases during the movement (for example, during the exposure of the substrate P) of the object opposed to the second member 22.

It should be noted that, when the second member 22 is moved during the movement (for example, during the exposure of the substrate F) of the object opposed to the second member 22, the relative movement between itself and the object (substrate P) opposed thereto may not decrease, and the second member 22 may not be moved.

In the present embodiment, even when the liquid LQ flows out from the space SP1, the liquid LQ, which flows out, can be captured in the liquid immersion space LS2. Consequently, occurrence of the exposure defects and production of defective devices can be suppressed.

### Third Embodiment

Next, the third embodiment will be described. In the following description, components the same as or equivalent to those of the above-mentioned embodiment are represented by the same reference signs, and a description thereof will be simplified or omitted here.

In the present embodiment, the second member 22 is moved such that the liquid LQ, which is present on the upper surface of the object, outside the liquid immersion space LS1 is captured in the liquid immersion space LS2. The liquid LQ, which is present on the upper surface of the object, includes the liquid LQ which is separated from the liquid immersion space LS1 and remains on the upper surface of the object. The liquid LQ, which is present on the upper surface of the object, includes the liquid LQ, which is not captured in the liquid immersion space LS2 and remains on the upper surface of the object such as the substrate P, in the liquid LQ separated from the liquid immersion space LS1. Further, the liquid LQ, which is present on the upper surface of the object, includes droplets of the liquid LQ.

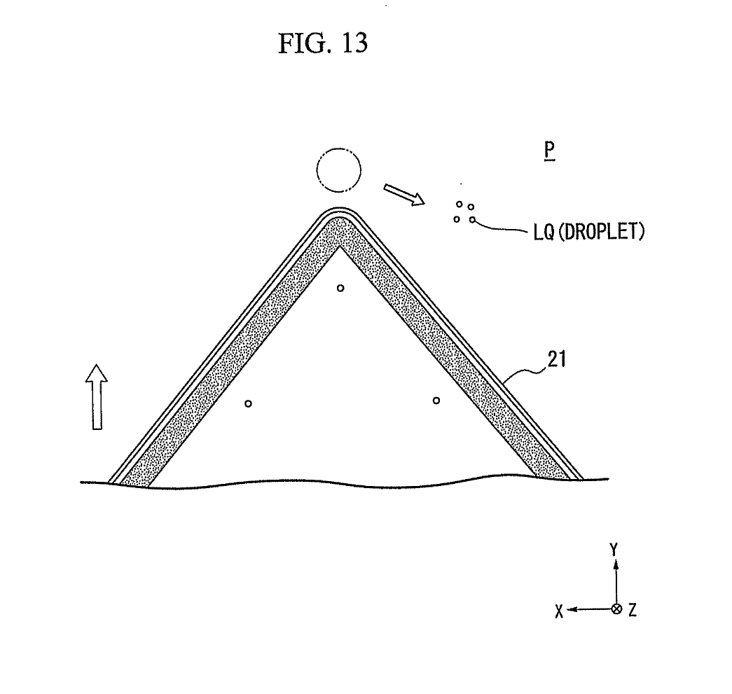

In the present embodiment, after completion of the exposure of the substrate P, as shown in FIG. 13, the control device 6 moves the second member 22 in order to collect (remove) the liquid LQ which remains on the substrate P. For example, before the exposure of the substrate P, from the movement condition of the object such as the substrate P or the like, the area (position) of the liquid LQ, which remains on the substrate P, is estimated, and after completion of the exposure of the substrate P, the second member 22 is moved such that the liquid immersion space LS passes the region, in which the liquid LQ is supposed to remain, on the substrate P. In the present embodiment, when the liquid LQ present (remaining) in the upper surface of the substrate P is removed, in a similar manner to the first embodiment, the second member 22 is moved such that the relative movement between itself and the substrate P opposed thereto decreases.

In the present embodiment, the second member 22 is also moved to track the substrate P. Accordingly, the liquid LQ, which is present on the upper surface of the substrate P, is easily captured by the second member 22, and is collected from the collection port 36. There is a possibility that droplets of the liquid LQ separated from the liquid immersion space LS1 are adhered onto the upper surface of the substrate P and remain on the substrate P. Since the second member 22 is moved to track the substrate F, the droplets of the liquid LQ adhered onto the upper surface of the substrate P can be easily collected from the collection port 36. That is, the second member 22 is moved to track the droplets of the liquid LQ adhered onto the upper surface of the substrate P, and thus it is possible to easily collect (remove) the droplets of the liquid LQ from the upper surface of the substrate P while inhibiting the droplets of the liquid LQ from being thinned on the substrate P.

Further, the second member 22 is moved such that the relative velocity (relative acceleration) between the second member 22 and the substrate P decreases. Thereby, the liquid LQ (the droplets of the liquid LQ), which is present on the upper surface of the substrate P, is easily captured by the second member 22, and is collected from the collection port 36.

It should be noted that, when the liquid LQ within the liquid immersion space LS2 flows out from the space SP2, by moving the second member 22, the liquid LQ, which flows out, can be captured in the liquid immersion space LS2, or can be collected from the collection port 36.

It should be noted that, in the present embodiment, when the second member 22 is moved in order to remove the liquid LQ on the substrate P opposed thereto, the relative movement between itself and the substrate P opposed thereto may not decrease, and the second member 22 may not be moved.

Further, when it is not necessary to dispose the second members 22 on the +Y side and the −Y side of the first member 21 during the exposure of the substrate P, during the exposure of the substrate P, as shown in FIG. 13, by moving the second member 22, the liquid LQ, which is present on the upper surface of the substrate P, may be collected (removed).

In the present embodiment, it is also possible to prevent the liquid LQ from remaining on the substrate P. Consequently, occurrence of the exposure defects and production of defective devices can be suppressed.

It should be noted that, in the present embodiment, in order to collect (remove) the liquid LQ which is present (remains) on the upper surface of the object other than the substrate P, the second member 22 may be moved.

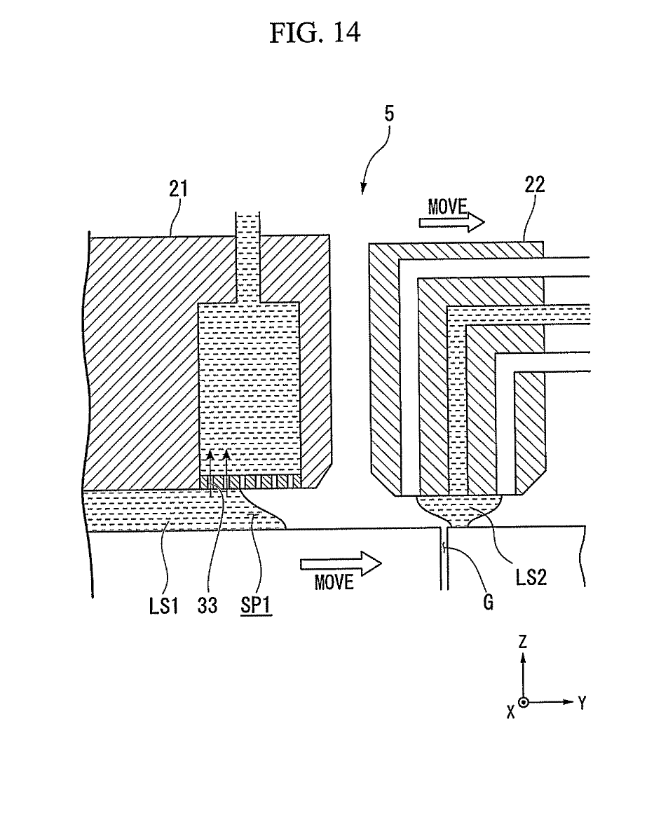

It should be noted that, in the above-mentioned embodiments, for example as shown in FIG. 14, the second member 22 is moved such that the relative velocity between itself and the object decreases when at least a part of the liquid immersion space LS2 is formed on the gap of the object. Further, the second member 22 may be moved such that the relative velocity between itself and the object decreases after at least a part of the liquid immersion space LS2 passes over the gap G of the object. Thereby, for example, the liquid immersion space LS2 (the interface LG2 of the liquid LQ within the liquid immersion space LS2) is held in the gap G, and the liquid LQ within the liquid immersion space LS2 is inhibited from flowing out from the space SP. Further, the liquid LQ is inhibited from remaining in the gap G.

In the present embodiment, for example as shown in FIG. 8, the gap G of the object includes at least one of a gap G1 between the substrate P, which is held in the first holding section 16, and the cover member T1 which is disposed at at least the part of the surrounding of the substrate P; a gap G2 between the cover member T1 and the scale member T2 which is disposed at at least a part of a surrounding of the cover member T1; and a gap between the substrate stage 2 and the measurement stage 3, which is disposed to approach the substrate stage 2, in the serum movement operation.

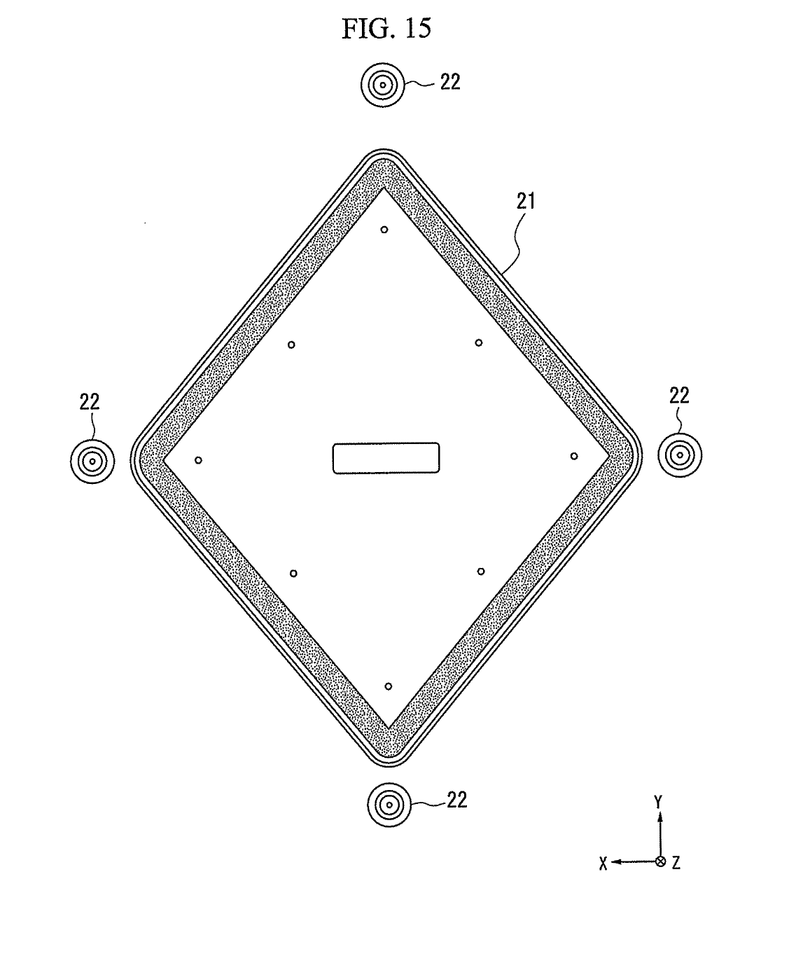

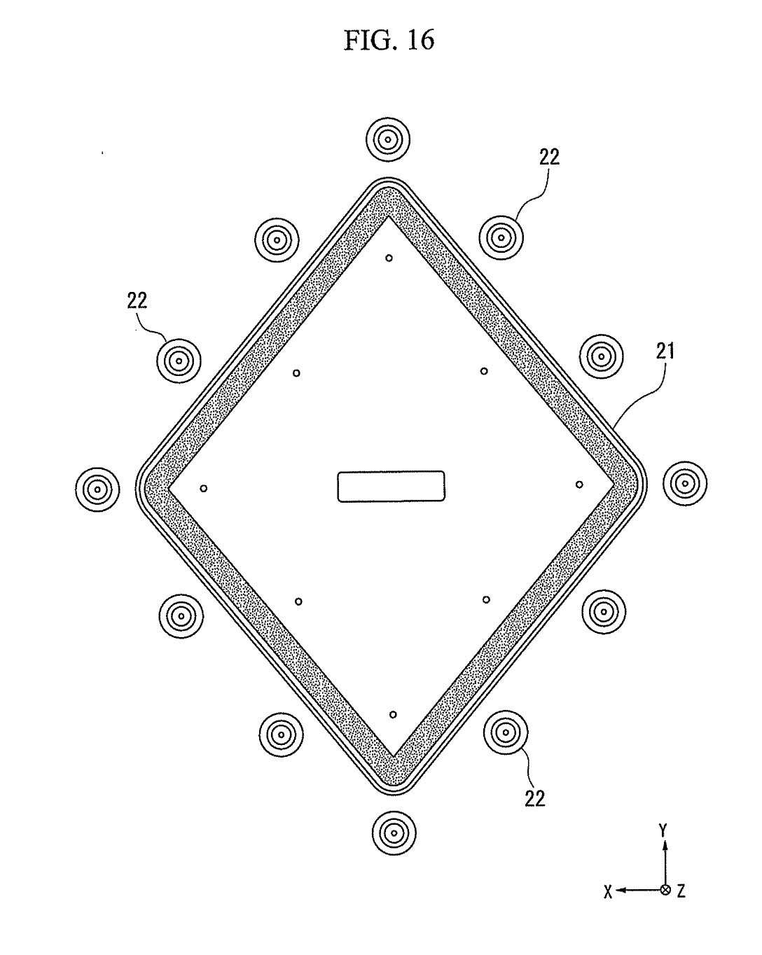

It should be noted that, in the above-mentioned embodiments, the second member 22 is disposed on at least one of the +Y side and the −Y side of the first member 21, but may be disposed on the +X side and the −X side of the first member 21, for example, as shown in FIG. 15. Further, as shown in FIG. 16, a plurality of second members 22 may be disposed around the first member 21. The number and the position of the second members 22 can be appropriately determined such that the liquid LQ does not remain on the object such as the substrate P opposed thereto in consideration of the movable range of the second members 22. Further, the plurality of second members 22 may be moved respectively in different directions. For example, the second member 22, which is disposed at a first position around the first member 21, and the second member 22, which is disposed at a second position different from the first position around the first member 21, may be moved in different directions. Further, the second member 22, which is disposed at the first position around the first member 21, may not be moved, and the second member 22, which is disposed at the second position different from the first position around the first member 21, may be moved. For example, as shown in FIG. 15, when four second members 22 are disposed, during the exposure of the substrate F, the second members 22, which are disposed on the +Y side and the −Y side of the first member 21, is not moved and is used in capturing (collecting) the liquid LQ which flows out (is separated) from the liquid immersion space LS1, and at least one of the second members 22, which are disposed on the +X side and the −X side of the first member 21, is moved. Thereby, the liquid LQ, which flows out (is separated) from the liquid immersion space LS1 and remains on the upper surface of the substrate P, may be collected (removed) in the liquid immersion space LS2. Further, when the plurality of second members 22 are provided, some of them may not be movable. Furthermore, when the plurality of second members 22 are provided, the position of one second member 22 thereof in the Z direction may be different from the position of another second member 22 in the Z direction.

### Fourth Embodiment

Next, the fourth embodiment will be described. In the following description, components the same as or equivalent to those of the above-mentioned embodiment are represented by the same reference signs, and a description thereof will be simplified or omitted here.

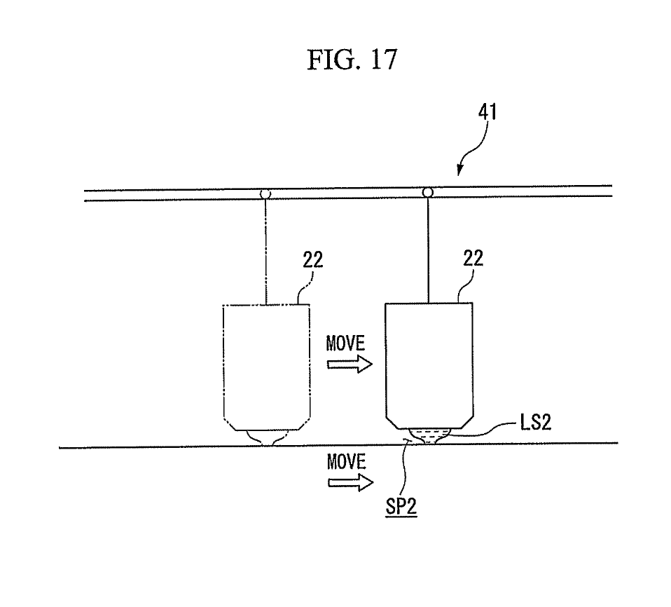

FIG. 17 is a schematic diagram illustrating an example of a supporting mechanism 41 that supports the second member 22 according to the present embodiment. The supporting mechanism 41 movably supports the second member 22. In the state where the liquid immersion space LS2 is formed, the object, which is in contact with the liquid LQ within the liquid immersion space LS2, is moved in the +Y direction relative to the second member 22, whereby the second member 22 is moved in the +Y direction. In the present embodiment, the second member 22 is actively moved by the movement of the object. That is, in the state where the liquid immersion space LS2 is formed between the second member 22 and the object, the object is moved in the +Y direction, whereby due to the effect of viscosity of the liquid LQ within the liquid immersion space LS2, the second member 22 is moved to track the object.

In the example shown in FIG. 17, it is possible to inhibit the liquid LQ within the liquid immersion space LS2 from flowing out from the space SP2. Further, the liquid LQ, which flows out from the space SP1, can be captured in the liquid immersion space LS2. Furthermore, the second member 22 is moved such that the relative velocity between itself and the object decreases. Renee, the liquid LQ within the liquid immersion space LS2 is inhibited from flowing out from the space SP2 or remaining on the object.

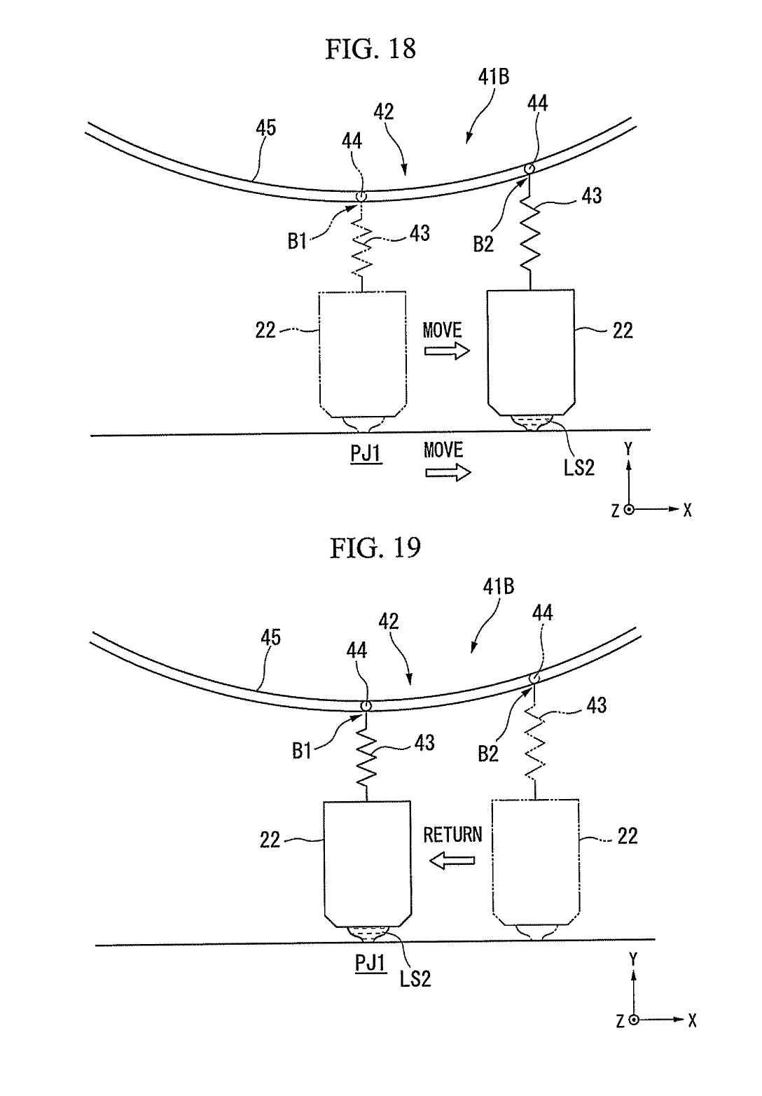

FIGS. 18 and 19 show an example in which the supporting mechanism 41B has a returning mechanism 42. The returning mechanism 42 is able to return the second member 22, which is moved from a certain returning position PJ1 around the first member 21, to the returning position PJ1.

The returning mechanism 42 includes: a supporting member 44 that supports the second member 22 through the elastic member 43; and a guiding mechanism 45 that includes a first portion B1, at which the supporting member 44 supporting the second member 22 disposed at the returning position PJ1 is disposed, and a second portion B2, which is disposed at a higher position than the first portion B1 and at which the supporting member 44 supporting the second member 22 moved from the returning position PJ1 is disposed, and that guides the supporting member 44 between the first portion B1 and the second portion B2.

As shown in FIG. 18, in the state where the liquid immersion space LS2 is formed, when the object is moved in the +Y direction, due to the effect of viscosity of the liquid LQ, the second member 22 is also moved in the +Y direction. As shown in FIG. 19, when the object is stopped, the supporting member 44, which is disposed at the second portion B2, is moved to the first portion B1 by the effect of gravity. The supporting member 44 is moved from the second portion B2 to the first portion B1, thereby returning the second member 22 to the returning position PJ1.

FIGS. 20 and 21 show an example in which the supporting mechanism 41C has a returning mechanism 42C. The returning mechanism 42C has an elastic mechanism 46 that applies force to the second member 22 such that it returns to the returning position PJ1. The elastic mechanism 46 includes: a first supporting member 47 that is connected to the second member 22; an elastic member 46A of which one end is connected to the side surface of the +Y side of the first supporting member 47 and the other end is connected to the second supporting member 48; and an elastic member 46B of which one end is connected to the side surface of the −Y side of the first supporting member 47 and the other end is connected to the second supporting member 48. As shown in FIG. 20, when the object is stopped, the second member 22 is disposed at the returning position PJ1. As shown in FIG. 21, when the object is moved in the +Y direction, the second member 22 is moved in the +Y direction. In this case, the elastic member 46A is contracted, and the elastic member 46B is expanded. When the object is stopped, the second member 22 is returned to the returning position PJ1 by the elastic force (biasing force) of the elastic members 46A and 46B.

### Fifth Embodiment

Next, the fifth embodiment will be described. In the following description, components the same as or equivalent to those of the above-mentioned embodiment are represented by the same reference signs, and a description thereof will be simplified or omitted here.

In the present embodiment, the second member 22 is movable by the driving system 30 as described in the first embodiment.

In the present embodiment, the second member 22 is moved such that the liquid immersion space LS2 is not formed on a predetermined portion of the object. The control device 6 controls the driving system 30 such that the liquid immersion space LS2 is not formed on the predetermined portion of the object, and controls the position of the second member 22.

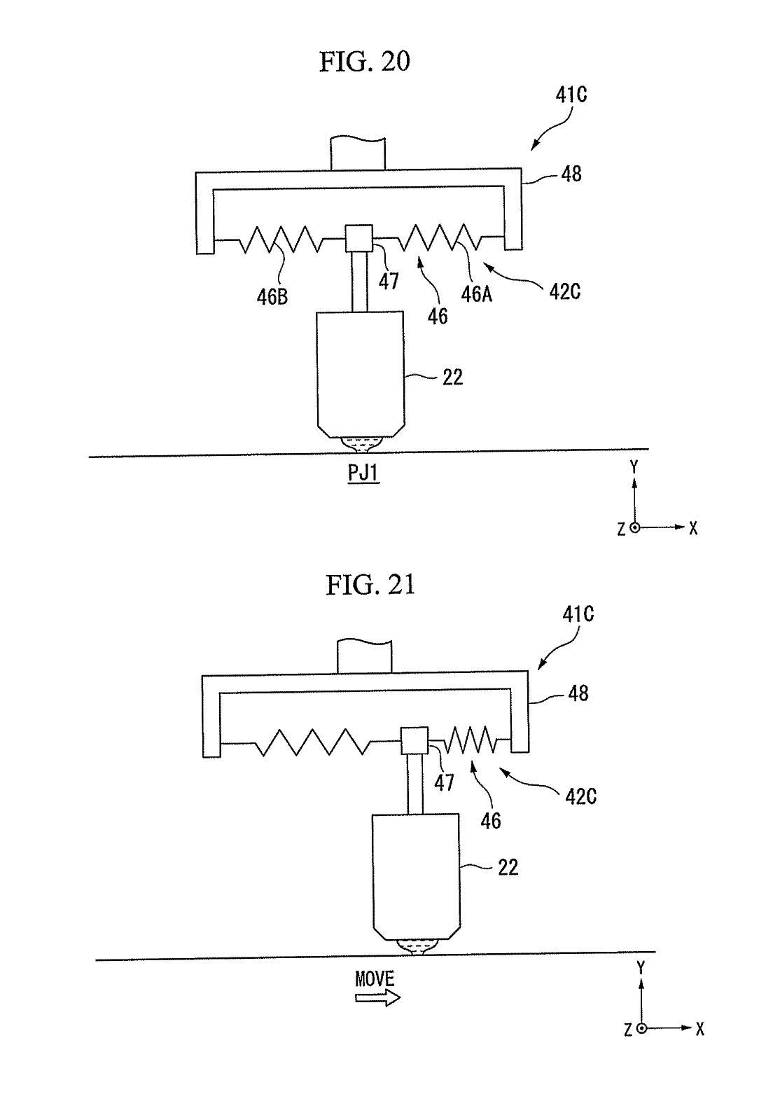

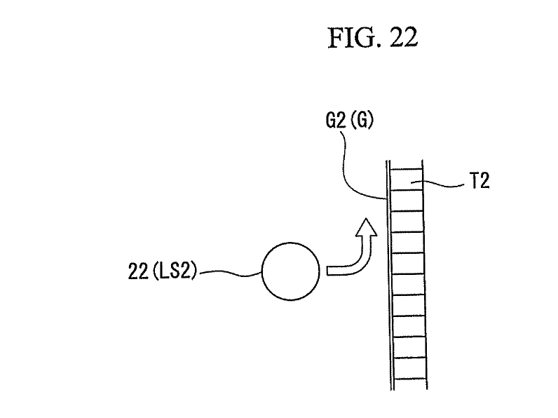

In the present embodiment, the predetermined portion includes at least one of at least a part of the scale member T2 and the gap G of the object. The gap G includes at least one of the gap G1 and the gap G2 mentioned above. For example, as shown in FIG. 22, the control device 6 controls the position of the second member 22 relative to the substrate stage 2 such that the liquid LQ within the liquid immersion space LS2 is not in contact with the gap G2 or the scale member T2.

The control device 6 controls the position of the second member 22 relative to the substrate stage 2 such that the liquid immersion space LS2 is not formed on the gap G2 or the scale member T2, based on the movement condition of the substrate stage 2. The control device 6 controls the position of the second member 22 relative to the substrate stage 2 such that the liquid immersion space LS2 is not formed on the predetermined portion of the object, based on, for example, the exposure control information (such as the movement condition of the substrate stage 2). It should be noted that the control device 6 may control the position of the second member 22 relative to the substrate stage 2 such that the liquid immersion space LS2 is not formed on the predetermined portion of the object, based on the measurement result of the measurement system 4.

For example, the liquid immersion space LS2 is not formed on the gap G (G2), thereby inhibiting the liquid LQ from remaining in the gap G. Further, the liquid immersion space LS2 is not formed on the scale member T2, thereby inhibiting the liquid LQ from remaining in the scale member T2. Thereby, occurrences of temperature changes caused by the remaining liquid LQ and deterioration in measurement accuracy are suppressed.

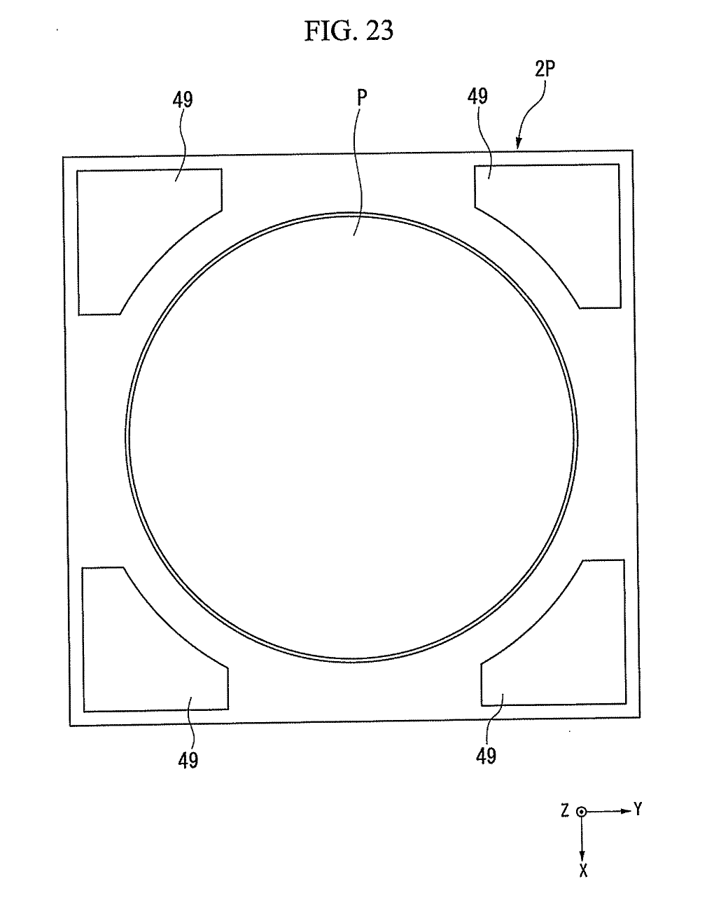

FIG. 23 shows an example of a substrate stage 2P. In FIG. 23, the substrate stage 2P has sensors 49 that measure the exposure light EL through the liquid LQ within the liquid immersion space LS1. Each sensor 49 includes an optical member that has the upper surface which is able to hold the liquid LQ between itself and the first member 21. A plurality of sensors 49 are disposed around the substrate P.

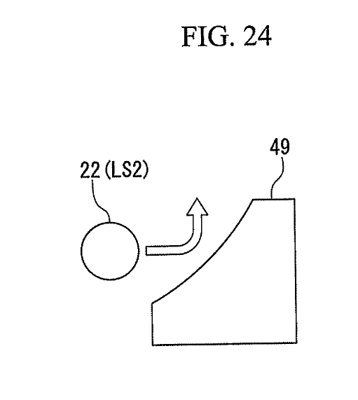

The predetermined portion includes the sensors 49. As shown in FIG. 24, the control device 6 controls the position of the second member 22 relative to the substrate stage 2P such that the liquid LQ within the liquid immersion space LS2 is not in contact with the sensor 49. Thereby, the liquid LQ is inhibited from remaining in the sensor 49.

It should be noted that it may suffice to control the position of the second member 22 (movement) so as to decrease the number of times the liquid immersion space LS2 is formed on the predetermined portion. For example, when the liquid immersion space LS2 is formed on the scale member T2 six times unless the second member 22 is moved, it may suffice to move the second member 22 such that the liquid immersion space LS2 is formed on the scale member T2 three times.

It should be noted that the present embodiment may also be applicable to the exposure apparatus EX in which the guiding section is not provided substantially on the first member 21 as described later.

### Sixth Embodiment

Next, the sixth embodiment will be described. In the following description, components the same as or equivalent to those of the above-mentioned embodiment are represented by the same reference signs, and the description thereof will be simplified or omitted.

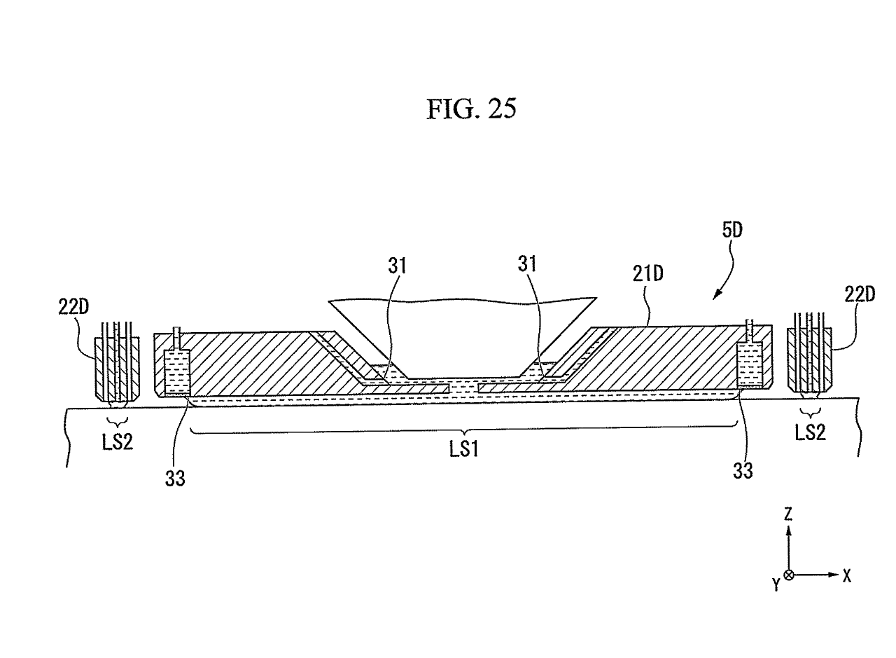

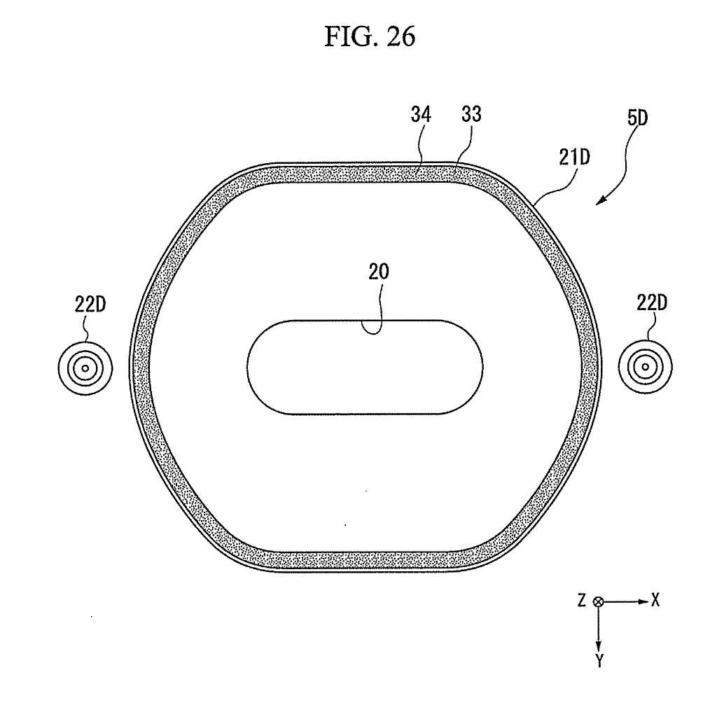

FIG. 25 is a diagram illustrating an example of a liquid immersion member 5D according to the present embodiment. FIG. 26 is a diagram of the liquid immersion member 5D viewed from the lower side.

In FIGS. 25 and 26, the liquid immersion member 5D has a first member 21D, which forms the liquid immersion space LS1, and second members 22D which form the liquid immersion spaces LS2. In the present embodiment, the first member 21D does not have a guiding section in practice. The first member 21D does not have a supply port opposed to the object (such as the substrate P), but may have the supply port. Each second member 22D has the same configuration as the second member 22 described in the above-mentioned embodiments. In the present embodiment, the second members 22D are respectively disposed on the +X side and the −X side of the first member 21D.

It should be noted that, although detailed description will be omitted, the first member 21D is fixed, and may be movable in at least one direction out of six directions of the X axis, Y axis, Z axis, θX, θY, and θZ directions. Further, the second member 22D is movable on the X axis, Y axis, and Z axis, but may not be moved in the Z axis direction, and may be movable in at least one direction out of θX, θY, and θZ.

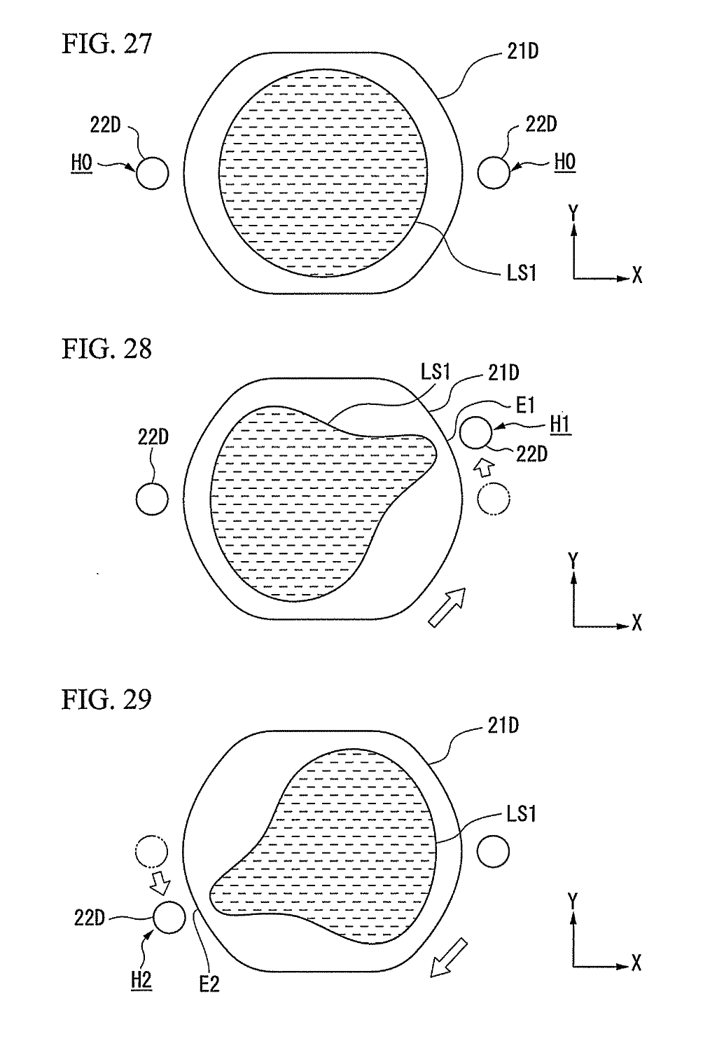

Hereinafter, referring to schematic diagrams of FIGS. 27 to 29, an example of the operation of the liquid immersion member 5D will be described. In the present embodiment, each second member 22D is movable by the driving system 30. The second member 22D, which is disposed on the +X side relative to the first member 21D, and the second member 22D, which is disposed on the −X side, are movable in different directions. Further, the second member 22D, which is disposed on the +X side relative to the first member 21D, and the second member 22D, which is disposed on the −X side, are separately movable. Furthermore, in a state where one of the second member 22D disposed on the +X side relative to the first member 21D and the second member 22D disposed on the −X side is stopped, the other may be moved.

FIG. 27 shows an example of the state where the object (such as the substrate P) is stopped. When the object is stopped, the liquid LQ does not flow out from the space SP1. The second members 22D are disposed at reference positions H0.

FIG. 28 shows an example in which the object is moved in the +X direction while being moved in the +Y direction. As shown in FIG. 28, by moving the object, the liquid LQ within the liquid immersion space LS1 flows in the space SP1. In the example shown in FIG. 28, the liquid LQ within the liquid immersion space LS1 is likely to flow out of the space SP1 from the position E1.

The second member 22D is moved such that the liquid LQ, which flows out from the space SP1, is captured in the liquid immersion space LS2. That is, the second member 22D is moved from the reference position H0 to the position H1 adjacent to the position E1. Thereby, although the liquid LQ flows out from the position E1, the liquid LQ, which flows out, is captured in the liquid immersion space LS2.

Further, as shown in FIG. 29, when the object is moved in the −X direction while being moved in the −Y direction, the liquid LQ within the liquid immersion space LS1 is likely to flow out of the space SP1 from the position E2.

The second member 22D is moved such that the liquid LQ, which flows out from the space SP1, is captured in the liquid immersion space LS2. That is, the second member 22D is moved from the reference position H0 to the position H2 adjacent to the position E2. Thereby, although the liquid LQ flows out from the position E2, the liquid LQ, which flows out, is captured in the liquid immersion space LS2.

The control device 6 moves the second member 22D based on the movement condition of the object or the like such that the liquid LQ, which flows out from the space SP1, is captured in the liquid immersion space LS2. The control device 6 moves the second member 22D based on information on at least one of the position (E1 or E2) and the direction of outflow of the liquid LQ from the space SP1, estimated from the movement condition of the object or the like.

That is, the control device 6 moves the second member 22D based on information on at least one of the position and the direction of outflow of the liquid LQ from the space SP1, estimated from the movement condition of the object. The information on the outflow position (outflow direction) of the liquid LQ based on the movement condition of the object or the like can be acquired by, for example, a preliminary experiment or a simulation. The information is stored in the storage device 7, whereby the control device 6 is able to move the second member 22D such that the liquid LQ is captured in the liquid immersion space LS2, based on the information of the storage device 7. Thereby, the liquid LQ is inhibited from flowing out.

It should be noted that, when the information on at least one of the position and the direction of outflow of the liquid LQ from the space SP1 can be acquired in advance, the second member 22D is moved in advance based on the information, and the second member 22D may not be moved during movement of the object such as the substrate P opposed thereto (for example, during the exposure of the substrate P).

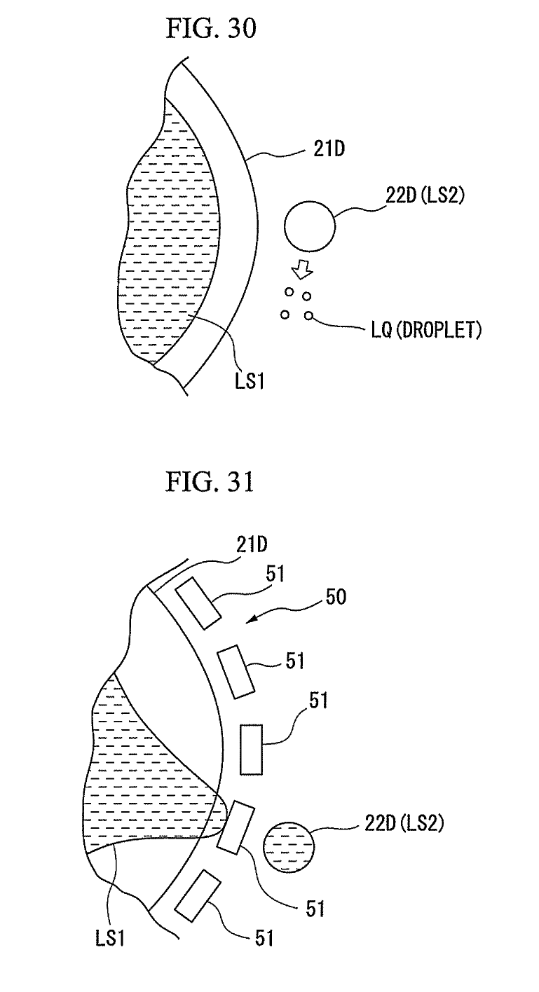

Further, the second member 22D may be moved such that the liquid LQ, which is present on the upper surface of the object, outside the liquid immersion space LS1 is captured in the liquid immersion space LS2. For example, as shown in FIG. 30, the liquid LQ is likely to be separated from the liquid immersion space LS1 and remain on the upper surface of the object. For example, the droplets of the liquid LQ are likely to be present (remain) on the upper surface of the object. The control device 6 may move the second member 22D in order to capture (remove) the liquid LQ, which is present on the upper surface of the object, in the liquid immersion space LS2.

The control device 6 may move the second member 22D based on the movement condition of the object or the like so as to capture the liquid LQ, which is present on the upper surface of the object, outside the liquid immersion space LS1, in the liquid immersion space LS2. The control device 6 may move the second member 22D based on information on the position of the liquid LQ, which is separated from the liquid immersion space LS1 and is present on the upper surface of the object, estimated from the movement condition of the object or the like.

That is, the control device 6 may move the second member 22D based on information on the position of the remaining liquid LQ, estimated from the movement condition of the object or the like. The information on the position of the remaining liquid LQ based on the movement condition of the object or the like is acquired by, for example, a preliminary experiment or a simulation. The information is stored in the storage device 7, whereby the control device 6 is able to move the second member 22D such that the liquid LQ is captured in the liquid immersion space LS2, based on the information of the storage device 7. Thereby, the liquid LQ is inhibited from flowing out.

It should be noted that, when the liquid LQ remaining on the upper surface of the object (such as the substrate P) is captured (removed) as shown in FIG. 30, the second member 22D may not be moved in order to collect (remove) the liquid LQ, which flows out from the space SP1, as described in FIGS. 28 and 29.

Further, one of the second member 22D, which is disposed on the +X side, and the second member 22D, which is disposed on the −X side, may be used to collect (remove) the liquid LQ, which flows out from the space SP1, as described in FIGS. 28 and 29, and the other may be used to capture (remove) the liquid LQ which remains on the upper surface of the object (such as the substrate P), as described in FIG. 3D. For example, in the period during which the plurality of shot regions arranged in the X axis direction on the substrate P are sequentially exposed while the substrate P is moved in the +X axis direction, as described in FIGS. 28 and 29, the second member 22D on the +X side of the first member 21 may be used to collect (remove) the liquid LQ which flows out from the space SP1, and the second member 22D on the −X side may be used to capture (remove) the liquid LQ which remains on the upper surface of the object (such as the substrate F), as described in FIG. 30.

Further, as shown in FIG. 31, there may be provided a detection device 50 that detects the liquid LQ which flows out from the space SP1. The detection device 50 has a plurality of detection sections 51 disposed around the first member 21D. Each detection section 51 includes an emission portion that emits detection light toward the object such as the substrate P and a light receiving portion that receives the detection light reflected by the object, and is able to detect whether the liquid LQ flows out from the space SP1 based on changes in the light receiving amount of the light receiving portion. The control device 6 is able to acquire the information on at least one of the position and the direction of outflow of the liquid LQ from the space SP1, based on the detection result of the detection device 50 (a plurality of detection sections 51).

The control device 6 controls the driving system 30 such that the liquid LQ, which flows out from the space SP1, is captured in the liquid immersion space LS2, based on the detection result of the detection device 50. The driving system 30 moves the second member 221D such that the liquid LQ is captured in the liquid immersion space LS2, based on the detection result of the detection device 50. Thereby, the liquid LQ is inhibited from remaining on the object such as the substrate P.

Further, as shown in FIG. 30, the detection device 50 may be disposed to be able to detect the liquid LQ which is separated from the liquid immersion space LS1 and is present (remains) on the upper surface of the object. In this case, the control device 6 is able to move the second member 22D such that the liquid LQ, which is separated from the liquid immersion space LS1 and is present (remains) on the upper surface of the object, is captured in the liquid immersion space LS2, based on the detection result of the detection device 50.

Furthermore, the detection device 50 may be disposed to detect the position of the liquid LQ which remains on at least one of the substrate P and the enclosing member T after the exposure of the substrate P.

For example, before the exposure of the substrate P, in the same mariner as the exposure operation performed on the substrate P, the position of the liquid LQ, which remains on the dummy substrate after the exposure operation of the dummy substrate is performed, is detected by using the detection device 50, and thereby based on the result, the movement of the second member 22D during the exposure operation thereafter performed on the substrate P may be controlled.

Alternatively, the position (region), at which the liquid LQ remains, is estimated based on the movement condition of the object or the like, the liquid immersion exposure operation of the substrate P is performed while the second member 22D is moved in accordance with the control information determined based on the estimation, subsequently the position of the liquid LQ, which remains on the substrate P, is detected by using the detection device 50, and based on the detection result, thereafter the movement of the second member 22D during the exposure operation performed on another substrate P on the same condition may be controlled. In this case, based on the detection result of the detection device 50, control information of the movement of the second member 22D determined based on the estimation may be edited (updated).

It should be noted that the detection method is not limited to the above-mentioned method. For example, the detection device 50 may be a camera (imaging device). Further, the detection method may not be an optical type.

Further, the control device 6 may move the second member 22D so as to capture the liquid LQ, which flows out from the space SP2, or the liquid LQ, which is separated from the liquid immersion space LS2 and remains on the object, in the liquid immersion space LS2.

In addition, the detection device 50 can be applied to the exposure apparatus EX having the first member 21 which is provided with the above-mentioned guiding section.

### Seventh Embodiment

Next, the seventh embodiment will be described. In the following description, components the same as or equivalent to those of the above-mentioned embodiment are represented by the same reference signs, and a description thereof will be simplified or omitted here.

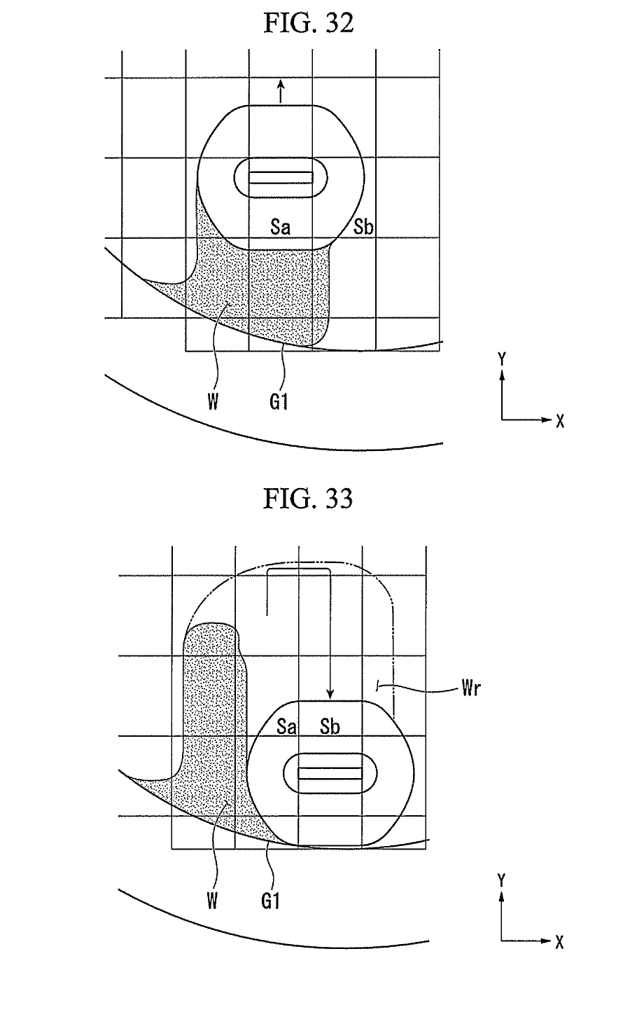

FIGS. 32 and 33 show an example of an operation of the exposure apparatus EX according to the present embodiment FIGS. 32 and 33 are diagrams schematically illustrating an example of the position of the substrate P (substrate stage 2) relative to the first member 21D at the time of exposing the shot region Sa of the substrate P and subsequently exposing the shot region Sb.

As shown in FIG. 32, when the shot region Sa is exposed through the liquid LQ within the liquid immersion space LS1, the substrate P is moved in the −Y direction relative to the projection region PR and the liquid immersion space LS1. In the example of FIG. 32, the region W of the upper surface of the substrate P, which is in contact with the liquid LQ within the liquid immersion space LS1, is a region in which the liquid LQ (droplets) separated from the liquid immersion space LS1 is highly likely to remain since the liquid immersion space LS1 is formed on the gap G1 before start of the exposure of the shot region Sa.

As shown in FIG. 33, when the shot region Sb is exposed, the substrate P is moved in the +Y direction relative to the projection region PR and the liquid immersion space LS1. In this case, the region Wr as a part of the region W comes into contact again with the liquid LQ within the liquid immersion space LS1 in at least a part of the period of the stepping movement operation before the exposure of the shot region Sb and the period of the stepping movement operation during the exposure (during the scanning operation movement) and after the exposure. That is, the region Wr (first region) which comes into contact again with the liquid immersion space LS1 and the region W (second region) which does not come into contact therewith are formed on the upper surface of the substrate P after coming into contact with the liquid immersion space LS1.

The region Wr is a region in which the liquid LQ (droplets) is less likely to remain. That is, although the liquid LQ remains in the region W by the first contact with the liquid LQ within the liquid immersion space LS1, the liquid LQ (droplets), which remains by the next contact with the liquid immersion space LS1, is captured by the liquid immersion space LS1 with which the liquid secondly comes into contact.

That is, the region W, which comes into contact with the liquid LQ within the liquid immersion space LS1 only once, is a region in which the liquid LQ (droplets) is highly likely to remain. Thus, it can be said that the region Wr, which comes into contact twice with the liquid LQ within the liquid immersion space LS1, is a region in which the liquid LQ (droplets) is less likely to remain.

In the present embodiment, the second member 22D is moved such that the liquid immersion space LS2 comes into contact with the region W. Thereby, the liquid LQ, which remains in the region W, is captured by the liquid immersion space LS2, and is removed from the substrate P (object). The position of the region W can be estimated from the exposure control information (such as the movement condition of the substrate P). The control device 6 moves the second member 22D such that the entire region of the region W, in which it is estimated that the liquid LQ is highly likely to remain, comes into contact with the liquid immersion space LS2 in the period before the exposure of the substrate P is completed.

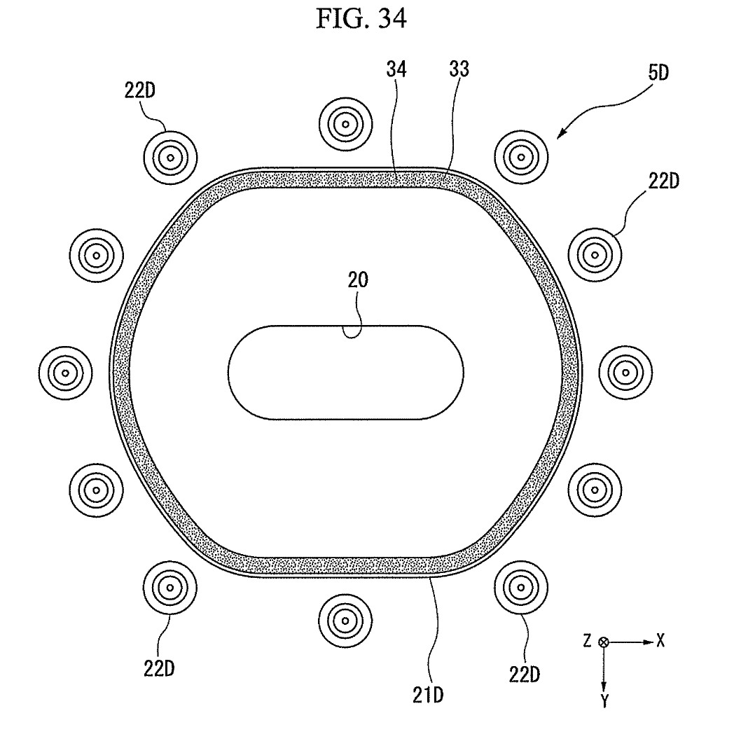

It should be noted that, in the sixth and seventh embodiments mentioned above, for example as shown in FIG. 34, a plurality of second members 22D are disposed around the first member 21D. The number and the position of the second members 22D can be determined such that the liquid LQ, which remains on the object such as the substrate P opposed thereto, is removed in consideration of the movable range of the second members 22D. In the case of FIG. 34, all of the plurality of second members 22D may also be moved at the same time, and in a state where at least one second member 22D is stopped, the remaining second members 22D may be moved. Further, at least one second member 22D may be used to collect (remove) the liquid LQ, which flows out from the space SP1, as described in FIGS. 28 and 29, and the remaining second members 22D may be used to capture (remove) the liquid LQ which remains on the upper surface of the object (such as the substrate P), as described in FIG. 30. Furthermore, when the plurality of second members 22D are provided, some of them may not be movable. In addition, when the plurality of second members 22D are provided, the position of one second member 22D thereof in the Z direction may be different from the position of another second member 22D in the Z direction.

Further, in the case where the liquid immersion member 5D according to the sixth or seventh embodiment is used, in a similar manner as the first to third embodiments mentioned above, when the liquid LQ on the object such as the substrate P opposed thereto is captured (removed), the second member 22D may be moved such that the relative movement between itself and the object opposed thereto decreases, and the second member 22D may be moved to track the movement of the object opposed thereto.

Furthermore, in the case of moving the second member (22, 22D) so as to decrease the relative movement (at least one of the relative velocity and the relative acceleration) between itself and the object opposed thereto, the second member (22, 22D) may be moved in advance in a direction intended to decrease at least one of the relative velocity and the relative acceleration and may start to be moved in the direction intended to decrease at least one of the relative velocity and the relative acceleration at the same time as the object is moved.

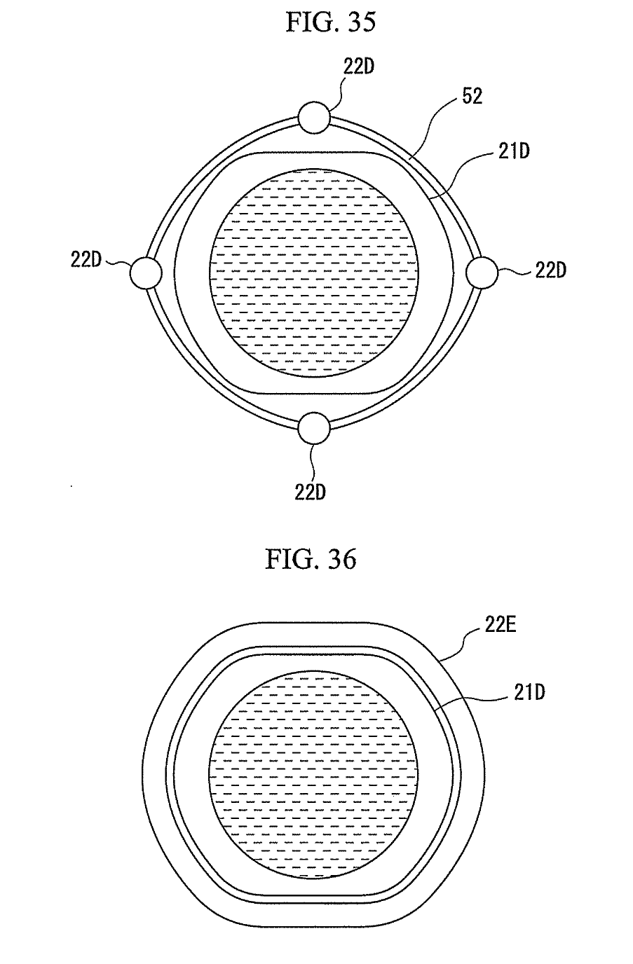

In addition, as shown in FIG. 35, a supporting mechanism 52 may be provided that supports the plurality of second members 22D disposed around the first member 21D together.

In addition, as shown in FIG. 36, a second member 22E, which has an annular shape forming an annular liquid immersion space around the first member 21D, may be movable in at least one direction out of six directions of the X axis, Y axis, Z axis, θX, θY, and θZ directions.

In addition, as described above, the control device 6 includes a computer system which includes a CPU and the like. Further, the control device 6 includes an interface, which is capable of conducting communication between the computer system and the external apparatus. The storage device 7 includes storage media such as a memory of RAM or the like, a hard disk, and a CD-ROM. In the storage device 7, an operating system (OS) that controls a computer system is installed, and a program for controlling the exposure apparatus EX is stored.

Further, the control device 6 may be connected to an input device that is capable of inputting an input signal. The input device includes input equipment, such as a keyboard and a mouse, or a communication device, which is capable of inputting data from the external apparatus. In addition, a display device, such as a liquid crystal display, may be provided.

Various kinds of information, including the program stored in the storage device 7, can be read by the control device 6 (computer system). In the storage device 7, a program is stored that causes the control device 6 to control the immersion exposure apparatus which exposes the substrate P to the exposure light through the first liquid which fills the optical path of the exposure light between the substrate and the emission surface of the optical member emitting the exposure light.

According to the embodiments mentioned above, the program stored in the storage device 7 may cause the control device 6 to execute the following functions of forming a first liquid immersion space of the first liquid by a first member, which is disposed at at least a part of a surrounding of an optical member such that the first liquid fills an optical path of the exposure light between the substrate and an emission surface of the optical member emitting the exposure light and has a first lower surface which can be opposed to the substrate opposed to the emission surface, in at least a part of a first space close to the first lower surface (a first space under the first lower surface) and an optical path space close to the emission surface (an optical path space under the emission surface); exposing the substrate through the first liquid within the first liquid immersion space; forming a second liquid immersion space of a second liquid separated from the first liquid immersion space, by a second member, which is disposed outside the first member with respect to the optical path and has a second lower surface which can be opposed to the substrate, in at least a part of a second space close to the second lower surface (a second space under the second lower surface); and moving the second member in the state where the second liquid immersion space is formed.

The program stored in the storage device 7 is read by the control device 6, thereby executing the various processes, such as the immersion exposure of the substrate P, in the state where the liquid immersion spaces LS1 and LS2 are formed, in cooperation with the various apparatuses of the exposure apparatus EX such as the substrate stage 2, the measurement stage 3, and the liquid immersion member 5.

Further, in the embodiments mentioned above, the liquid LQ for forming the liquid immersion space LS1 and the liquid LQ for forming the liquid immersion space LS2 may be the same type (physical property) and may be different types (physical property).

Furthermore, in the embodiments mentioned above, the optical path K on the emission surface 12 (imaging plane side) of the terminal optical element 13 of the projection optical system PL is filled with the liquid LQ. However, as disclosed in, for example, PCT International Publication No. WO2004/019128, the projection optical system PL may be a projection optical system in which the optical path on the incident side (object surface side) of the terminal optical element 13 is also filled with the liquid LQ.

Moreover, in the embodiments mentioned above, water is used as the liquid LQ, but a liquid other than water may be used. Preferably, the liquid LQ is a liquid that is transparent with respect to the exposure light EL, has a high refractive index with respect to the exposure light EL, and is stable with respect to the projection optical system PL or the film of the photosensitive material (photoresist) or the like that forms the front surface of the substrate P. For example, the liquid LQ may be a fluorine-based liquid such as hydro-fluoro-ether (HFE), perfluorinated polyether (PFPE), or Fomblin oil. In addition, the liquid LQ may be any of various fluids, such as, for example, a supercritical fluid.

In addition, in the embodiments mentioned above, the substrate P includes a semiconductor wafer for fabricating semiconductor devices, but may include, for example, a glass substrate for display devices, a ceramic wafer for thin film magnetic heads, or the original plate of a mask or a reticle (a synthetic quartz or a silicon wafer) used by an exposure apparatus.

In addition, in the embodiments mentioned above, the exposure apparatus EX is a step-and-scan type scanning exposure apparatus (scanning stepper), which scans and exposes the pattern of the mask M by synchronously moving the mask M and the substrate P, but may be, for example, a step-and-repeat type projection exposure apparatus (stepper), which performs the one-shot exposure on the pattern of the mask M in a state where the mask M and the substrate P remain stationary and then sequentially moves the substrate P in steps.

Further, the exposure apparatus EX may be an exposure apparatus (stitching type one-shot exposure apparatus) that performs the one-shot exposure on the substrate P, in the exposure of the step-and-repeat type, by transferring a reduced image of a first pattern onto the substrate P through the projection optical system in a state where the first pattern and the substrate P are substantially stationary, and subsequently by transferring a reduced image of a second pattern onto the substrate P such that it partially overlaps with the first pattern through the projection optical system in a state where the second pattern and the substrate P are substantially stationary. Furthermore, the stitching type exposure apparatus may be a step-and-stitch type exposure apparatus that transfers at least two patterns onto the substrate P such that they partially overlap with each other and sequentially moves the substrate P.

Furthermore, the exposure apparatus EX may be an exposure apparatus that combines, on the substrate, the patterns of two masks through a projection optical system and double exposes, substantially simultaneously, a single shot region on the substrate using a single scanning exposure, as disclosed in, for example, U.S. Pat. No. 6,611,316. Furthermore, the exposure apparatus EX may be a proximity type exposure apparatus, a mirror projection aligner, and the like.

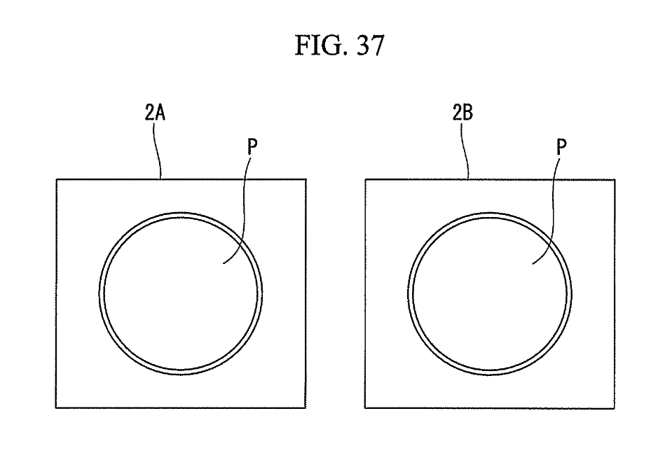

In addition, in the embodiments mentioned above, the exposure apparatus EX may be a twin stage type exposure apparatus, which includes a plurality of substrate stages, as disclosed in, for example, U.S. Pat. Nos. 6,341,007, 6,208,407, and 6,262,796. For example, as shown in FIG. 37, when the exposure apparatus EX includes two substrate stages 2A and 2B, the object, which can be disposed to be opposed to the emission surface 12, includes at least one of one substrate stage, a substrate which is held by the first holding section of the one substrate stage, the other substrate stage, and a substrate which is held by the first holding section of the other substrate stage.

Moreover, the exposure apparatus EX may be an exposure apparatus that includes a plurality of the substrate stages and the measurement stages.

The exposure apparatus EX may be a semiconductor device fabrication exposure apparatus that exposes the pattern of a semiconductor device on the substrate P, and may be an exposure apparatus used for fabricating, for example, liquid crystal display devices or displays, or an exposure apparatus for fabricating thin film magnetic heads, image capturing devices (CCDs), micromachines, MEMS, DNA chips, or reticles and masks.

In addition, in the embodiments mentioned above, the optically transmissive mask M, in which a predetermined shielding pattern (or phase pattern or dimming pattern) is formed on an optically transmissive substrate, is used. However, instead of such a mask, as disclosed in, for example, U.S. Pat. No. 6,778,257, it may be possible to use a variable shaped mask (also called an electronic mask, an active mask, or an image generator), in which a transmissive pattern, a reflective pattern, or a light emitting pattern is formed based on electronic data of the pattern to be exposed. Further, instead of a variable shaped mask that includes a non-emissive type image display device, a pattern forming apparatus that includes a self-luminous type image display device may be provided.

In the embodiments mentioned above, the exposure apparatus EX includes the projection optical system PL. However, the components described in the above-mentioned embodiments may be used in an exposure apparatus and an exposing method that does not use the projection optical system PL. For example, the liquid immersion space is formed between the substrate and an optical member such as a lens, whereby the substrate P can be irradiated with the exposure light through the optical member. In the exposure apparatus and the exposure method using such a configuration, the components described in the above-mentioned embodiments may be used.

Further, the exposure apparatus EX may be an exposure apparatus (lithographic system) that exposes the substrate P with a line-and-space pattern by forming interference fringes on the substrate P, as disclosed in, for example, PCT International Publication No. WO2001/035168.

The exposure apparatus EX according to the embodiments mentioned above is manufactured by assembling various subsystems, which include the above-mentioned components, such that predetermined mechanical, electrical, and optical accuracies are maintained. To ensure these various accuracies, adjustments are performed before and after this assembly, including an adjustment to achieve optical accuracy for the various optical systems, an adjustment to achieve mechanical accuracy for the various mechanical systems, and an adjustment to achieve electrical accuracy for the various electrical systems. The process of assembling the exposure apparatus from the various subsystems includes, for example, the connection of mechanical components, the wiring and connection of electrical circuits, and the piping and connection of the pneumatic circuits among the various subsystems. It is needless to say that, prior to performing the process of assembling the exposure apparatus from these various subsystems, there are also the processes of assembling each individual subsystem. After the process of assembling the exposure apparatus from the various subsystems is complete, a comprehensive adjustment is performed to ensure the various accuracies of the exposure apparatus as a whole. It should be noted that it is preferable to manufacture the exposure apparatus in a clean room, in which the temperature, the cleanliness level, and the like are controlled.

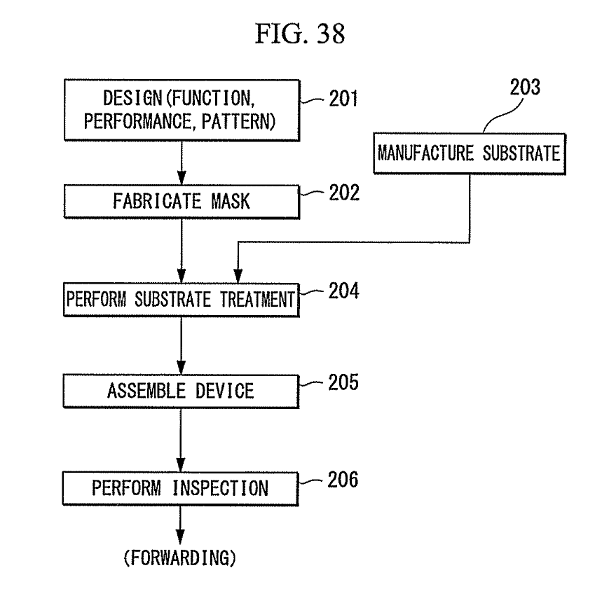

As shown in FIG. 38, a micro device, such as a semiconductor device, is manufactured by: a step 201 that designs the functions and performance of the micro device; a step 202 that fabricates the mask (reticle) based on this designing step; a step 203 that manufactures the substrate, which is the base material of the device; a substrate treatment step 204 that includes a substrate treatment (exposure process) that includes, in accordance with the embodiments mentioned above, exposing the substrate with the exposure light emitted from the pattern of the mask and developing the exposed substrate; a device assembling step 205 (which includes fabrication processes such as dicing, bonding, and packaging processes); an inspecting step 206; and the like.

In addition, the features of each embodiment mentioned above can be combined as appropriate. Further, there are also cases in which some of the components are not used. Furthermore, each disclosure of every Japanese published patent application and US patent related to the exposure apparatus recited in the embodiments mentioned above, the modified examples, and the like is hereby incorporated by reference in its entirety to the extent permitted by national laws and regulations.

The following listing of claims will replace all prior versions, and listings, of claims in the application:

1. An exposure apparatus that exposes a substrate with exposure light through a first liquid, the exposure apparatus comprising:
an optical member that has an emission surface which emits the exposure light;
a first member that is disposed at at least a part of a surrounding of the optical member and forms a first liquid immersion space of the first liquid, the first member having a first lower surface to which an object can be opposed, the object being capable of moving to a position opposed to the emission surface, the first liquid immersion space being formed in at least a part of a first space under the first lower surface and an optical path space including an optical path of the exposure light from the emission surface; and
a second member that is disposed outside the first member with respect to the optical path and forms a second liquid immersion space of a second liquid, the second member having a second lower surface to which the object can be opposed, the second liquid immersion space being formed in at least a second space under the second lower surface, the second member being capable of moving in a state where the second liquid immersion space is formed separated from the first liquid immersion space.

2. The exposure apparatus according to claim 1, wherein the second member is moved such that a relative velocity between itself and the object decreases.

3. The exposure apparatus according to claim 2, wherein the second member is moved such that the relative velocity between itself and the object decreases less than a relative velocity between the first member and the object.

4. The exposure apparatus according to claim 2, wherein the second member is moved such that the relative velocity between itself and the object decreases when at least a part of the second liquid immersion space is formed on a gap of the object.

5. The exposure apparatus according to claim 2, wherein the second member is moved such that the relative velocity between itself and the object decreases after at least a part of the second liquid immersion space passes over a gap of the object.

6. The exposure apparatus according to claim 2, wherein the second member is moved to track the object.

7. The exposure apparatus according to claim 1, wherein the second member is moved such that the second liquid immersion space is not formed on a predetermined portion of the object.

8. The exposure apparatus according to claim 7, wherein the predetermined portion includes the gap of the object.

9. The exposure apparatus according to claim 7, wherein the predetermined portion includes at least a part of a measurement member.

10. The exposure apparatus according to claim 7, wherein the predetermined portion includes at least a part of a sensor which measures the exposure light through the first liquid within the first liquid immersion space.

11. The exposure apparatus according to claim 4, wherein the gap includes a gap between the substrate and a cover member which is disposed at at least a part of a surrounding of the substrate.

12. The exposure apparatus according to claim 4, wherein the gap includes a gap between the cover member, which is disposed at at least a part of a surrounding of the substrate, and the measurement member which is disposed at at least a part of a surrounding of the cover member.

13. The exposure apparatus according to claim 1, wherein the second member is moved to capture the first liquid, which flows out from the first space, in the second liquid immersion space.

14. The exposure apparatus according to claim 1, wherein the second member is moved to capture the first liquid, which is present on an upper surface of the object, outside the first liquid immersion space, in the second liquid immersion space.

15. The exposure apparatus according to claim 14, wherein the first liquid, which is present on the upper surface of the object, includes the first liquid which is separated from the first liquid immersion space and remains on the upper surface of the object.

16. The exposure apparatus according to claim 14, wherein the first liquid, which is present on the upper surface of the object, includes droplets of the first liquid.

17. The exposure apparatus according to claim 1, further comprising a detection device that detects the first liquid which flows out from the first space,
wherein the second member is moved based on a detection result of the detection device.

18. The exposure apparatus according to claim 17, wherein the detection device detects the first liquid which is separated from the first liquid immersion space and is present on the upper surface of the object.

19. The exposure apparatus according to claim 1, wherein the second member is moved based on a movement condition of the object.

20. The exposure apparatus according to claim 19, wherein the second member is moved based on information on at least one of a position and a direction of outflow of the first liquid from the first space, estimated from the movement condition of the object.

21. The exposure apparatus according to claim 19, wherein the second member is moved based on information on a position of the first liquid, which is separated from the first liquid immersion space and is present on the upper surface of the object, estimated from the movement condition of the object.

22. The exposure apparatus according to claim 19, wherein the movement condition includes at least one of a movement velocity, an acceleration, a movement direction, and a movement locus of the object.

23. The exposure apparatus according to claim 19,
wherein the upper surface of the object includes, after coming in contact with the first liquid immersion space, a first region which comes in contact again with the first liquid immersion space and a second region which does not come in contact therewith, and
wherein the second member is moved such that the second liquid immersion space comes in contact with the second region.

24. The exposure apparatus according to claim 1, further comprising a driving system that moves the second member.

25. The exposure apparatus according to claim 1, further comprising a supporting mechanism that movably supports the second member,
wherein in a state where the second liquid immersion space is formed, the object, which is in contact with the second liquid within the second liquid immersion space, is moved relative to the second member, thereby moving the second member in a direction in which the object is moved.

26. The exposure apparatus according to claim 25, wherein the second member is passively moved by movement of the object.

27. The exposure apparatus according to claim 25, further comprising a returning mechanism that returns the second member, which is moved from a certain returning position around the first member, to the returning position.

28. The exposure apparatus according to claim 27, wherein the returning mechanism includes an elastic mechanism which applies a force to the second member so as to return the second member to the returning position.

29. The exposure apparatus according to claim 27, wherein the returning mechanism has
a supporting member that supports the second member through an elastic member, and
a guiding mechanism that includes a first portion, in which the supporting member supporting the second member located at the returning position is disposed, and a second portion, which is disposed at a higher position than the first portion and in which the supporting member supporting the second member moved from the returning position is disposed, so as to guide the supporting member between the first portion and the second portion.

30. The exposure apparatus according to claim 1, further comprising a guiding section that guides at least a part of the first liquid within the first liquid immersion space into a guiding space at a part of a surrounding of the optical path,
wherein the second member captures at least a part of the first liquid, which flows out from the first space through the guiding section, in the second liquid immersion space.

31. The exposure apparatus according to claim 30, wherein at least a part of the guiding section is disposed in the first member.

32. The exposure apparatus according to claim 1,
wherein in the state where the second liquid immersion space is formed, each shot region on the substrate is exposed while the substrate is moved in the first direction which is substantially perpendicular to an optical axis of the optical member, and
wherein the second member is disposed on at least one of one side and the other side of the first member in the first direction.

33. The exposure apparatus according to claim 1,
wherein another second member is additionally disposed on at least one of one side and the other side of the first member in a second direction which intersects with the first direction.

34. The exposure apparatus according to claim 1,
wherein in the state where the second liquid immersion space is formed, each shot region on the substrate is exposed while the substrate is moved in the first direction which is substantially perpendicular to the optical axis of the optical member, and
wherein the second member is disposed on at least one of one side and the other side of the first member in a second direction which is substantially perpendicular to the optical axis of the optical member and intersects with the first direction.

35. The exposure apparatus according to claim 1, wherein a plurality of the second members are disposed around the first member.

36. The exposure apparatus according to claim 35, wherein the second member, which is disposed at a first position around the first member, and the second member, which is disposed at a second position different from the first position around the first member, are movable in different directions.

37. The exposure apparatus according to claim 35, further comprising a supporting mechanism that supports the plurality of the second members.

38. The exposure apparatus according to claim 1, wherein the object is movable in a predetermined plane and the second member is moved in parallel to the predetermined plane.

39. The exposure apparatus according to claim 1, wherein the second member is movable in substantially parallel to the upper surface of the object opposed to the second lower surface.

40. The exposure apparatus according to claim 1, wherein the second member is movable in substantially parallel to a surface which is perpendicular to the optical axis of the optical member.

41. The exposure apparatus according to claim 1, wherein the second member is movable to approach the upper surface of the object opposed to the second lower surface or to be separated from the upper surface of the object.

42. The exposure apparatus according to claim 1, wherein the second member is movable in substantially parallel to the optical axis of the optical member.

43. The exposure apparatus according to claim 1, wherein the second member can be tilted with respect to the upper surface of the object opposed to the second lower surface.

44. The exposure apparatus according to claim 1, wherein the second member can be tilted with respect to a surface which is perpendicular to the optical axis of the optical member.

45. The exposure apparatus according to claim 1,
wherein the second member has a supply port that supplies the second liquid and a collection port that collects the second liquid, and
wherein the second liquid immersion space is formed by collecting the second liquid from the collection port while supplying the second liquid from the supply port.

46. The exposure apparatus according to claim 45, wherein the collection port collects the first liquid together with the second liquid within the second liquid immersion space.

47. The exposure apparatus according to claim 45, wherein the collection port collects the second liquid together with gas.

48. The exposure apparatus according to claim 1, further comprising a substrate stage that is movable while holding the substrate,
wherein the object includes at least one of the substrate which is held on the substrate stage and at least a part of the substrate stage.

49. The exposure apparatus according to claim 1, wherein the first member is movable in at least one direction of a direction parallel to the optical axis of the optical member, a direction around an axis parallel to the optical axis of the optical member, a direction perpendicular to the optical axis of the optical member, and a direction around an axis perpendicular to the optical axis of the optical member.

50. The exposure apparatus according to claim 1, further comprising a projection optical system that includes the optical member,
wherein the substrate is irradiated with exposure light through the first liquid between the substrate and the emission surface of the optical member.

51. A device manufacturing method comprising:
exposing a substrate by using the exposure apparatus according to claim 1; and
developing the exposed substrate.

52. An exposure method of exposing a substrate with exposure light through a first liquid, the exposure method comprising:
forming a first liquid immersion space of the first liquid with a first member, the first member being disposed at at least a part of a surrounding of an optical member such that the first liquid fills an optical path of the exposure light between the substrate and an emission surface of the optical member that emits the exposure light and having a first lower surface to which the substrate opposed to the emission surface can be opposed, the first liquid immersion space being formed in at least a part of a first space under the first lower surface and an optical path space under the emission surface;
exposing the substrate through the first liquid in the first liquid immersion space;
forming a second liquid immersion space of a second liquid with a second member, the second member being disposed outside the first member with respect to the optical path and having a second lower surface to which the substrate can be opposed, the second liquid immersion space being formed in at least a part of a second space under the second lower surface; and
moving the second member in the state where the second liquid immersion space is formed separated from the first liquid immersion space.

53. A device manufacturing method comprising:
exposing a substrate by using the exposure method according to claim 52; and
developing the exposed substrate.

54. A program causing a computer to control an exposure apparatus, which exposes a substrate with exposure light through a first liquid, by executing:
forming a first liquid immersion space of the first liquid with a first member, the first member being disposed at at least a part of a surrounding of an optical member such that the first liquid fills an optical path of the exposure light between the substrate and an emission surface of the optical member that emits the exposure light and having a first lower surface to which the substrate opposed to the emission surface can be opposed, the first liquid immersion space being formed in at least a part of a first space under the first lower surface and an optical path space under the emission surface;
exposing the substrate through the first liquid in the first liquid immersion space;
forming a second liquid immersion space of a second liquid with a second member, the second member being disposed outside the first member with respect to the optical path and having a second lower surface to which the substrate can be opposed, the second liquid immersion space being formed in at least a part of a second space under the second lower surface; and
moving the second member in the state where the second liquid immersion space is formed separated from the first liquid immersion space.

55. A computer-readable recording medium storing the program according to claim 54.
